(19) United States
(12) Patent Application Publication
(10) Pub. No.: US 2011/0096609 A1
(43) Pub. Date: Apr. 28, 2011

(54) Novel punch-through free program scheme for nt-string flash design

(75) Inventors: Peter Wung Lee, Saratoga, CA (US); Fu-Chang Hsu, San Jose, CA (US)

(73) Assignee: Aplus Flash Technology, Inc.

(21) Appl. No.: 12/925,489

(22) Filed: Oct. 22, 2010

Related U.S. Application Data
(60) Provisional application No. 61/279,660, filed on Oct. 23, 2009.

(51) Int. Cl. G11C 16/10; G11C 16/04; H01L 27/088

(52) U.S. Cl. 365/185.28; 365/185.18; 257/314; 257/E27.06

(57) ABSTRACT

A nonvolatile memory array has nonvolatile memory cells arranged in rows and columns where each column has a bit line and source line associated with and in parallel with the nonvolatile memory cells. In programming the nonvolatile memory cell, approximately equal program voltage levels are applied to a drain and a source of a selected charge retaining transistor such that the difference in the voltage between the drain and the source of the selected charge retaining transistor is less than a drain to source breakdown voltage of the selected charge retaining transistor to prevent drain-to-source punch through. In programming or erasing the nonvolatile memory cell a control gate and a bulk program voltage level is applied to a control gate and bulk such that the magnitude of the control gate and bulk program voltage levels is less than a breakdown voltage level of peripheral circuitry.

### BACKGROUND OF THE INVENTION

This application claims priority under 35 U.S.C. §119 to U.S. Provisional Patent Application U.S. Provisional Patent Application Ser. No. 61/279,660, filed on Oct. 23, 2009, assigned to the same assignee as the present invention, and incorporated herein by reference in its entirety.

### RELATED PATENT APPLICATIONS

U.S. patent application Ser. No. 12/456,744, filed Jun. 22, 2009 assigned to the same assignee as the present invention, and incorporated herein by reference in its entirety.
U.S. patent application Ser. No. 12/387,771, filed May 7, 2009 assigned to the same assignee as the present invention, and incorporated herein by reference in its entirety.
U.S. patent application Ser. No. 12/455,337, filed Jun. 1, 2009 assigned to the same assignee as the present invention, and incorporated herein by reference in its entirety.
Attorney's Docket Number AP09-009, U.S. patent application Ser. No. ______, filed ______assigned to the same assignee as the present invention, and incorporated herein by reference in its entirety.

### FIELD OF THE INVENTION

This invention relates generally to nonvolatile memory array structure and operation. More particularly, this invention relates to a NAND and NOR flash nonvolatile memory device structure and operation. More particularly, this invention relates to a NAND and NOR flash nonvolatile memory device structure and operation to prevent source-to-drain punch through during programming of charge retaining transistors of the NAND and NOR cells and to prevent over-erasure leakage currents during reading of selected charge retaining transistors of the NAND and NOR cells.

### DESCRIPTION OF RELATED ART

Nonvolatile memory is well known in the art. The different types of charge retaining nonvolatile memory include Read-Only-Memory (ROM), Electrically Programmable Read Only Memory (EPROM), Electrically Erasable Programmable Read Only Memory (EEPROM), NOR Flash Memory, and NAND Flash Memory. In current applications such as personal digital assistants, cellular telephones, notebook and laptop computers, voice recorders, global positioning systems, etc., the Flash Memory has become one of the more popular types of Nonvolatile Memory. Flash Memory has the combined advantages of the high density, small silicon area, low cost and can be repeatedly programmed and erased with a single low-voltage power supply voltage source.

The Flash Memory structures known in the art employ a charge retaining mechanism such as a charge storage phenomena and a charge trapping phenomena. In a charge storage mechanism, as with a floating gate nonvolatile memory, the charge representing digital data is stored on a floating gate of the device. The stored charge modifies the threshold voltage of the floating gate memory cell to determine the digital data stored. In a charge trapping mechanism, as in a Silicon-Oxide-Nitride-Oxide-Silicon (SONOS) or Metal-Oxide-Nitride-Oxide-Silicon (MONOS) type cell, the charge is trapped in a charge trapping layer between two insulating layers. The charge trapping layer in the SONOS/MONOS devices has a relatively high dielectric constant (k) such Silicon Nitride (SiNₓ).

A present day flash nonvolatile memory is divided into two major product categories such as the fast random-access, asynchronous NOR flash nonvolatile memory and the slower serial-access, synchronous NAND flash nonvolatile memory. NOR flash charge retaining nonvolatile memory devices as presently designed is the high pin-count memory with multiple external address and data pins along with appropriate control signal pins. One disadvantage of NOR flash nonvolatile memory is as the density is doubled, the number of its required external pin count increases by one due to the adding of one more external address pin. In contrast, NAND flash nonvolatile memory has an advantage of having a smaller pin-count than NOR with no address input pins. As density increases, the NAND flash nonvolatile memory pin count is always kept constant. Both NAND and NOR flash nonvolatile memory cell structures in production today use a one charge retaining (charge storage or charge trapping) transistor memory cell that stores one bit of data as charge or as it commonly referred to as a single-level cell program cell (SLC). They are respectively referred as one-bit/one transistor NAND cell or NOR cell, storing a single-level cell programmed data in the cell. The single-level cell programmed cell has two voltage thresholds (Vt0 and Vt1) representing the one bit of data retained by the charge retaining transistor.

The NAND and NOR flash nonvolatile memory provides the advantage of in-system program and erase capabilities and have a specification for providing at least 100K endurance cycles. In addition, both single-chip NAND and NOR flash nonvolatile memory product can provide giga-byte density because their highly-scalable cell sizes. For instance, presently a one-bit/one transistor NAND cell size is kept at ˜4λ² (λbeing a minimum feature size in a semiconductor process), while NOR cell size is ˜10λ².

NOR flash memories cells are arranged in an array, of rows and columns in a NOR-like structure. All the NOR Flash cells on each row share the same word line. The drain electrodes that are common to two cells on each column are commonly connected to the bit line (BL) associated with each column. Sources of each of the NOR flash cells of each of the rows of the array are commonly connected to the source lines that are commonly connected and are often connected to the ground reference voltage source. Similarly, the NAND flash memories cells are arranged in an array, of rows and columns in a NAND-like structure. All the charge retaining transistors on each row of the NAND Flash cells share a common word line. The drain electrodes of a topmost charge retaining transistor of each NAND flash memory cell on each column is in communication with the bit line (BL) associated with the column. Sources of each of the NAND flash memory cells of the array are commonly connected to the source lines that are commonly connected and are often connected to the ground reference voltage source.

Currently, the highest-density of a single-chip double polycrystalline silicon gate NAND flash nonvolatile memory chip is 64 Gb. In contrast, a double polycrystalline silicon gate NOR flash nonvolatile memory chip has a density of 2 Gb. The big gap between NAND and NOR flash nonvolatile memory density is a result of the superior scalability of NAND flash nonvolatile memory cell over a NOR flash nonvolatile memory. A NOR flash nonvolatile memory cell requires 5.0V drain-to-source (Vds) to maintain a high-current Channel-Hot-Electron (CHE) programming process. Alternately, a NAND flash nonvolatile memory cell requires 0.0V between the drain to source for a low-current Fowler-Nordheim channel tunneling program process. The above results in the one-bit/one transistor NAND flash nonvolatile memory cell size being only one half that of a one-bit/one transistor NOR flash nonvolatile memory cell. This permits a NAND flash nonvolatile memory device to be used in applications that require huge data storage. A NOR flash charge retaining nonvolatile memory device is extensively used as a program-code storage memory which requires less data storage and requires fast and asynchronous random access.

A common concern for the NOR-type flash nonvolatile memory array designs of the prior art is a bit line leakage current that occurs for a read operation and for a program operation using either the channel-hot-electron or Fowler-Nordheim edge program operations. The bit line leakage current creates more of a problem in program operations than read operations, because the program operation of the NOR-type flash nonvolatile memory cells requires a +5.0V bit line voltage to create a drain-to-source voltage (Vds) of 5.0V which creates punch through in the depletion region of the channel during programming. Alternately, the read operation has a drain-to-source voltage (Vds) of approximately +1.0V. The larger bit line voltage (+5.0V) is coupled to floating-gate of the NOR-type flash nonvolatile memory cell. This induces a positive voltage at the floating gate which causes conduction of a sub-threshold leakage current if the NOR-type flash nonvolatile memory cells erased threshold voltage Vt0 is less than +10.0V.

In the read operation, if each of the NOR-type flash nonvolatile memory cells has a low threshold voltage Vt0, each cell will conduct more than 10 nA leakage with bit lines set to a read bias voltage level of approximately +1.0V and the source lines set to a voltage level of approximately the ground reference voltage level (0.0V). Each bit line will conduct a leakage current of about 10 μA if all 1024 cells connected to the bit line have a low threshold voltage Vt0. The total leakage current for the total NOR-type flash nonvolatile memory array is approximately 10 mA bit line leakage induced to all of the 1024 bit lines. In a normal read operation, each selected NOR-type flash nonvolatile memory cell would conduct approximately 20-40 μA to the bit line to the connected sense amplifier when reading a selected NOR-type flash nonvolatile memory cell. The remaining 1023 of (N−1) unselected NOR-type flash nonvolatile memory cells would have leakage of 10 μA creating the possibility of a read error or false read. In the worst-case, if each NOR-type flash nonvolatile memory cell conducts more than 10 μA, then the read operation will fail.

In the program operation, if each of the NOR-type flash nonvolatile memory cells has a low threshold voltage level VT0, each of the NOR-type flash nonvolatile memory cells will conduct approximately 1 μA leakage current when the bit line has approximately +5.0V applied to it and the source line has a voltage level that is approximately the ground reference voltage level (0.0V). Each bit line with a total of 1024 NOR-type flash nonvolatile memory cells connected to the bit line could possibly conduct a leakage current of approximately 1 mA [1K cells×1 μA/cell; assuming 1024 word lines by 1024 bit lines configured as a unit array]. If the total NOR-type flash nonvolatile memory array had NOR-type flash nonvolatile memory cells with the low threshold voltage level Vt0, then the total leakage current would ˜1 A [1K cells×1 mA/cell; assuming 1024 word lines by 1024 bit lines configured as a unit array]. In normal channel hot electron program operation, each selected NOR-type flash nonvolatile memory cell on the selected bit line would only conduct approximately 100 μA per cell. As a result, the 1023 unselected NOR-type flash nonvolatile memory cell leakage of 1 mA and the program operation would fail, regardless of whether the program operation is a Channel-Hot-Electron program operation.

### SUMMARY OF THE INVENTION

An object of this invention is to provide a charge retaining (floating gate or SONOS charge trapping) transistor flash NAND and NOR nonvolatile memory cells.

Another object of this invention is to provide an N-channel and a P-channel charge retaining (floating gate or SONOS charge trapping) transistor for flash NAND and NOR nonvolatile memory cells.

Further, another object of this invention is to provide an array of charge retaining (floating gate or SONOS charge trapping) transistor flash NAND and NOR nonvolatile memory cells having a bit line and a source line parallel with each column of the charge retaining transistors.

Further still, another object of this invention is to provide method of operating an array of charge retaining (floating gate or SONOS charge trapping) transistor flash NAND and NOR nonvolatile memory cells where drain-to-source punch through is prevented.

Another object of this invention is to provide a method of operating an array of charge retaining transistor flash NAND and NOR nonvolatile memory cells such that program voltage levels applied to a control gate of a selected charge retaining and to a bulk region of the charge retaining have a magnitude less than a breakdown voltage of transistors forming peripheral circuits generating and distributing the program voltage levels.

To accomplish at least one of these objects, embodiments of a flash memory cell are formed of a select transistor serially connected with a string of at least one charge retaining transistors. In various embodiments, the flash memory cell has the select transistor and a single charge retaining transistor to form a NOR flash memory cell. In other embodiments, the flash memory cell has the select transistor and two or more charge retaining transistors to form a NAND flash memory cell. In various embodiments, the flash memory cell has the select transistor and thirty-two charge retaining transistors.

The source of the select transistor is connected to the drain of a topmost of the string of at least one charge retaining transistors. The drain of the select transistor is connected to a local bit line and the source of a bottommost of the string of the at least one dual charge retaining transistors is connected to a local source line. The drain/sources of the commonly connected dual serially connected charge retaining transistors of the string of at least one charge retaining transistors are connected solely together. The drain and sources are formed in a diffusion well. In some embodiments, the diffusion well is formed directly on a substrate. In other embodiments the diffusion well is formed in a deep diffusion well.

In some embodiments, the select transistor and the string of at least one charge retaining transistors are N-channel charge retaining transistors. In other embodiments, the select transistor and the string of at least one charge retaining transistors are P-channel charge retaining transistors. In still other embodiments, the N-channel select transistor and the string of at least one N-channel charge retaining transistors are formed in a P-type well. In various embodiments, the P-type well is formed in deep N-type well that is formed in a P-type substrate. In various embodiments, the P-type well is formed in an N-type substrate. In still other embodiments, the P-channel select transistor and the string of at least one P-channel charge retaining transistors are formed in an N-type well. In various embodiments, the N-type well is formed in deep P-type well that is formed in a N-type substrate. In various embodiments, the N-type well is formed in a P-type substrate.

In various embodiments, each charge retaining transistor of the string of at least one charge retaining transistors has a charge retaining layer that is formed of a charge storing polycrystalline floating gate layer or a metal layer. In some embodiments, the select transistor is formed of a floating gate charge retaining transistor where the floating gate and the control gate are shorted. In other embodiments, each charge retaining transistor of the string of at least one charge retaining transistors has a charge retaining layer that is formed of a charge trapping insulating layer where the charge trapping insulating layer is a silicon nitride forming a silicon oxide nitride oxide silicon (SONOS) structure.

In various embodiments, the local bit line connected to the drain of the select transistor and the local source line connected to the source of the bottommost charge retaining transistor of the string of at least one charge retaining transistors are parallel with each other and are parallel to an associated column of flash memory cells within an array of the flash memory cells. In some embodiments, the local bit lines and local source lines are formed of metal conductors formed on the surface of the substrate above the associated column of flash memory cells.

In various embodiments, programming and erasing biasing voltages are applied to a control gate, a drain or source, and a bulk region of a string of at least one charge retaining transistors to inject charge to or from the charge retaining layer to selectively program or erase the selected charge retaining transistor(s) of the string of at least one charge retaining transistors. The program and erase voltage levels are selected to have a magnitude less than the source-to-drain breakdown voltage of transistors of the peripheral circuitry that generates and distributes the program and erase biasing voltages. The programming voltages that are applied to the sources and drains of the selected charge retaining transistors are essentially equal to prevent punch through during programming.

In various embodiments, programming and erasing biasing voltages are applied to a control gate, a drain or source, and a bulk region of a string of at least one charge retaining transistors to inject charge to or from the charge retaining layer to selectively program or erase the selected charge retaining transistor(s) of the string of at least one charge retaining transistors. The program and erase voltage levels are selected to have a magnitude less than the source-to-drain breakdown voltage of transistors of the peripheral circuitry that generates and distributes the program and erase biasing voltages. The programming voltages that are applied to the sources an drains of the selected charge retaining transistors are essentially equal to prevent punch through during programming. In some embodiments, the selected charge retaining transistor of the string of at least one charge retaining transistors is programmed and erased by a Fowler-Nordheim tunneling. In various embodiments, the Fowler-Nordheim tunneling is through a channel region between the drain and source of the selected charge retaining transistor. In various embodiments, the Fowler-Nordheim tunneling is through an edge of a drain and/or source of the selected charge retaining transistor. In assorted embodiments, the threshold voltage levels of the charge retaining transistors have a positive magnitude for a programmed state and a negative magnitude of an erased state. In some embodiments, where the charge retaining transistors have charge retaining transistors have the positive magnitude for a programmed state and the negative magnitude of an erased state, the charge retaining transistors are N-channel charge retaining transistors. In other embodiments, the threshold voltage levels of the charge retaining transistors have a negative magnitude for a programmed state and a positive magnitude for an erased state. In some embodiments, where the charge retaining transistors have charge retaining transistors have the negative magnitude for a programmed state and the positive magnitude of an erased state, the charge retaining transistors are P-channel charge retaining transistors.

In some embodiments, where the flash memory cell is a NAND or NOR flash memory cell and the serially connected charge retaining transistors are N-channel floating gate transistors are formed in a triple P-well in a deep N-well, the programming biasing voltages are a positive program voltage level (approximately 10V+/−2V) applied to the control gate, a select gate voltage level (approximately 2V) applied to the gate of the select transistor, a drain/source program voltage level (approximately −8V+/−2V) applied to the drain of the select gate transistor and the source of the bottommost of the serially connected charge retaining transistors, the negative triple well program voltage level (approximately −8V+/−2V) applied to the triple P-well, and a well biasing voltage level that is the voltage level of the power supply voltage source (VDD) applied to the deep N-well. The erase biasing voltages are a positive select voltage level to the gate of the select transistor and a negative erase voltage level (approximately −10V+/−2V) applied to the control gate and a positive well erase voltage level (approximately 8V+/−2V) applied to the triple P-well and the deep N-well and coupled to the drain/source and source/drain of the serially connected charge retaining transistors. During erasing, the select gate is set to the well erase voltage level (approximately 8V+/−2V) to prevent stress in the gate oxide of the select transistor.

In still other embodiments, where the flash memory cell is a NAND or NOR flash memory cell and the serially connected charge retaining transistors are N-channel SONOS charge trapping transistors formed in a triple P-well in a deep N-well, the programming biasing voltages are a positive program voltage level (approximately 7V+/−1V) applied to the control gate, select voltage level (approximately 2V) applied to the gate of the select transistor, a negative drain/source program voltage level (−5V+/−1V) applied to the drain/source and source/drain of the serially connected charge retaining transistors and to the triple P-well, and a deep well biasing voltage level that is the voltage level of the power supply voltage source (VDD) applied to the deep N-well. The erasing biasing voltages are a negative erase voltage level (approximately −7V+/−1V) applied to the control gate, a positive well erase voltage level (approximately 5V+/−1V) applied to the triple P-well and to the deep N-well and coupled to the drains and sources of the select transistor and the serially connected charge retaining transistors. During erasing, the select gate is set to the biasing erase voltage level (approximately 5V+/−1V) to prevent stress in the gate oxide of the select transistor.

In other embodiments, where the flash memory cell is a NAND or NOR flash memory cell and the serially connected charge retaining transistors are P-channel floating gate transistors formed in a triple N-well in a deep P-well, the programming biasing voltages are a negative program voltage level (−10V+/−2V) applied to the control gate, a select voltage level (approximately −2V) applied to the gate of the select transistor, a positive drain/source program voltage level (8V+/−2V) applied to the drain of the select transistor and the source of the bottommost of the serially connected charge retaining transistors, and a well biasing voltage level (approximately 8V+/−2V) applied to the triple N-well, and a well biasing voltage level that is the voltage level of the ground (0V) applied to the deep P-well. The erasing biasing voltages are a positive erase voltage level (approximately 10V+/−2V) applied to the control gate, and a negative well biasing erase voltage level (approximately −8V+/−2V) applied to the triple N-well and to the deep P-well and coupled to the drain of the select transistor and the drains and sources of the serially connected charge retaining transistors. During erasing, the select gate is set to the well biasing erase voltage level (approximately −8V+/−2V) to prevent stress in the gate oxide of the select transistor.

In other embodiments, where the flash memory cell is a NAND or NOR flash memory cell and the serially connected charge retaining transistors are P-channel SONOS charge trapping transistors formed in a triple N-well in deep P-well, the programming biasing voltages are a negative program voltage level (approximately −7V+/−1V) applied to the control gate, gate select voltage level (approximately −2V) to the gate of the select transistor, a positive drain/source program voltage level (5V+/−1V) applied to the drain of the select transistor and source of the bottommost charge retaining transistor of the serially connected charge retaining transistors, and a well biasing voltage level (approximately 5V+/−1V) applied to the triple N-well, and a well biasing voltage level that is the voltage level of the ground (0V) applied to the deep P-well. The erasing biasing voltages are a positive erase voltage level (approximately 7V+/−1V) applied to the control gate and a negative erase well biasing voltage level (approximately −5V+/−1V) applied to the triple N-well and to the deep P-well and coupled to the drain/source and source/drain of the serially connected charge retaining transistors. During erasing, the select gate is set to the well biasing erase voltage level (approximately −5V+/−1V) to prevent stress in the gate oxide of the select transistor.

In some embodiments, where the flash memory cell is a NOR flash memory cell and the serially connected charge retaining transistors are N-channel floating gate transistors are formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −10V+/−2V) applied to the control gate, a select gate voltage level (approximately 7V) applied to the gate of the select transistor, a drain/source program voltage level (approximately 5V+/−2V) applied to the drain of the select gate transistor and the source of the bottommost of the serially connected charge retaining transistors, the ground voltage level (approximately 0V) applied to the triple P-well, and a well biasing voltage level that is the voltage level of the power supply voltage source (VDD) applied to the deep N-well. The erase biasing voltages are a positive select voltage level to the gate of the select transistor and a positive erase voltage level (approximately 10V+/−2V) applied to the control gate and a negative well erase voltage level (approximately −8V+/−2V) applied to the triple P-well and coupled to the drain/source and source/drain of the serially connected charge retaining transistors, and a power supply voltage (VDD) level is applied to the deep N-well. During erasing, the select gate is set to the well erase voltage level (approximately −8V+/−2V) to prevent stress in the gate oxide of the select transistor.

In still other embodiments, where the flash memory cell is a NOR flash memory cell and the serially connected charge retaining transistors are N-channel SONOS charge trapping transistors formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −7V+/−1V) applied to the control gate, select voltage level (approximately 7V+/−1V) applied to the gate of the select transistor, a drain/source program voltage level (5V+/−1V) applied to the drain/source and source/drain of the serially connected charge retaining transistors, a triple well biasing voltage (0V) applied to the triple P-well, and a deep well biasing voltage level that is the voltage level of the power supply voltage source (VDD) applied to the deep N-well. The erasing biasing voltages are a positive erase voltage level (approximately 7V+/−1V) applied to the control gate, a negative well biasing erase voltage level (approximately −5V+/−1V) applied to the triple P-well and coupled to the drains and sources of the select transistor and the serially connected charge retaining transistors, and a power supply voltage level (VDD) is applied to the deep N-well. During erasing, the select gate is set to the negative well biasing erase voltage level (approximately −5V+/−1V) to prevent stress in the gate oxide of the select transistor.

In other embodiments, where the flash memory cell is a NOR flash memory cell and the serially connected charge retaining transistors are P-channel floating gate transistors formed in a single N-well, the threshold voltage levels representing erased serially connected charge retaining transistors and the threshold voltage level representing programmed serially connected charge retaining transistors are reversed. The programming biasing voltages are a positive program voltage level (10V+/−2V) applied to the control gate, a select voltage level (approximately −7V+/−2V) applied to the gate of the select transistor, a negative drain/source program voltage level (−5V+/−2V) applied to the drain of the select transistor and the source of the bottommost of the serially connected charge retaining transistors, and a well biasing power supply voltage level (VDD) applied to the N-well. The erasing biasing voltages are a negative erase voltage level (approximately −10V+/−2V) applied to the control gate, and a positive well biasing erase voltage level (approximately 8V+/−2V) applied to the N-well and coupled to the drain of the select transistor and the drains and sources of the serially connected charge retaining transistors. During erasing, the select gate is set to the well biasing erase voltage level (approximately 8V+/−2V) to prevent stress in the gate oxide of the select transistor.

In other embodiments, where the flash memory cell is a NOR flash memory cell and the serially connected charge retaining transistors are P-channel SONOS charge trapping transistors formed in an N-well, the threshold voltage levels representing erased serially connected charge retaining transistors and the threshold voltage level representing programmed serially connected charge retaining transistors are reversed. The programming biasing voltages are a positive program voltage level (approximately 7V+/−1V) applied to the control gate, gate select voltage level (approximately −7V) to the gate of the select transistor, a negative drain/source program voltage level (−5V+/−1V) applied to the drain of the select transistor and source of the bottommost charge retaining transistor of the serially connected charge retaining transistors, and a well biasing power source voltage level (VDD) applied to the N-well. The erasing biasing voltages are a negative erase voltage level (approximately −7V+/−1V) applied to the control gate and a positive erase well biasing voltage level (approximately 5V+/−1V) applied to the N-well and coupled to the drain/source and source/drain of the serially connected charge retaining transistors. During erasing, the select gate is set to the well biasing erase voltage level (approximately 5V+/−1V) to prevent stress in the gate oxide of the select transistor.

In various embodiments, a nonvolatile memory device has an array of flash memory cells arranged in rows and columns. Each row of the array of flash memory cells is associated with a pair of word lines. Each column of the array of flash memory cells is associated with a bit line and a source line arranged to be in parallel with the associated column of flash memory cells. Each of the flash memory cells is formed of a select transistor serially connected with a string of at least one charge retaining transistors. In various embodiments, each flash memory cell of the array of flash memory cells has the select transistor and a single charge retaining transistor to form a NOR flash memory cell. In other embodiments, each flash memory cell has the select transistor and two or more charge retaining transistors to form a NAND flash memory cell. In some embodiments, each flash memory cell of the array of flash memory cells has the select transistor and thirty-two charge retaining transistors.

In each of the flash memory cells, the source of the select transistor is connected to the drain of a topmost of the string of at least one charge retaining transistors. The drain of the select transistor is connected to a local bit line and the source of a bottommost of the string of the at least one dual charge retaining transistors is connected to a local source line. The drain/sources of the commonly connected dual serially connected charge retaining transistors of the string of at least one charge retaining transistors are connected solely together. The drain and sources of each of the flash memory cells of the array of flash memory cells are formed in a diffusion well. In some embodiments, the diffusion well is formed directly on a substrate. In other embodiments the diffusion well is formed in a deep diffusion well.

In some embodiments of the array of flash memory cells, the select transistor and the string of at least one charge retaining transistors are N-channel charge retaining transistors. In other embodiments of the array of flash memory cells, the select transistor and the string of at least one charge retaining transistors are P-channel charge retaining transistors. In still other embodiments of the array of flash memory cells, the N-channel select transistor and the string of at least one N-channel charge retaining transistors are formed in a P-type well. In various embodiments of the array of flash memory cells, the P-type well is formed in deep N-type well that is formed in a P-type substrate. In various embodiments of the array of flash memory cells, the P-type well is formed in an N-type substrate. In still other embodiments of the array of flash memory cells, the P-channel select transistor and the string of at least one P-channel charge retaining transistors are formed in an N-type well. In various embodiments of the array of flash memory cells, the N-type well is formed in deep P-type well that is formed in a N-type substrate. In various embodiments, the N-type well is formed in a P-type substrate.

In various embodiments of the array of flash memory cells, each charge retaining transistor of the string of at least one charge retaining transistors has a charge retaining layer that is formed of a charge storing polycrystalline floating gate layer or a metal layer. In some embodiments of the array of flash memory cells, the select transistor is formed of a floating gate charge retaining transistor where the floating gate and the control gate are shorted. In other embodiments of the array of flash memory cells, each charge retaining transistor of the string of at least one charge retaining transistors has a charge retaining layer that is formed of a charge trapping insulating layer where the charge trapping insulating layer is a silicon nitride forming a silicon oxide nitride oxide silicon (SONOS) structure.

In various embodiments of the array of flash memory cells, the local bit line connected to the drain of the select transistor and the local source line connected to the source of the bottommost charge retaining transistor of the string of at least one charge retaining transistors are parallel with each other and are parallel to an associated column of flash memory cells within an array of the flash memory cells. In some embodiments, the local bit lines and local source lines are formed of metal conductors formed on the surface of the substrate above the associated column of flash memory cells.

In various embodiments of the nonvolatile memory device, programming and erasing biasing voltages are applied to a control gate, a drain or source, and a bulk region of a string of at least one charge retaining transistors to inject charge to or from the charge retaining layer to selectively program or erase the selected charge retaining transistor(s) of the string of at least one charge retaining transistors. The program and erase voltage levels are selected to have a magnitude less than the source-to-drain breakdown voltage of transistors of the peripheral circuitry that generates and distributes the program and erase biasing voltages. The programming voltages that are applied to the sources and drains of the selected charge retaining transistors are essentially equal to prevent punch through during programming. In some embodiments the selected charge retaining transistor of the string of at least one charge retaining transistors is programmed and erased by a Fowler-Nordheim tunneling. In various embodiments, the Fowler-Nordheim tunneling is through a channel region between the drain and source of the selected charge retaining transistor. In various embodiments, the Fowler-Nordheim tunneling is through an edge of a drain and/or source of the selected charge retaining transistor. In assorted embodiments, the threshold voltage levels of the charge retaining transistors have a positive magnitude for a programmed state and a negative magnitude of an erased state. In some embodiments of the nonvolatile memory device, where the charge retaining transistors have charge retaining transistors have the positive magnitude for a programmed state and the negative magnitude of an erased state, the charge retaining transistors are N-channel charge retaining transistors. In other embodiments the threshold voltage levels of the charge retaining transistors have a negative magnitude for a programmed state and a positive magnitude for an erased state. In some embodiments of the nonvolatile memory device, where the charge retaining transistors have charge retaining transistors have the negative magnitude for a programmed state and the positive magnitude of an erased state, the charge retaining transistors are P-channel charge retaining transistors.

In some embodiments of the nonvolatile memory device, where each of the flash memory cells is a NAND or NOR flash memory cell and the serially connected charge retaining transistors are N-channel floating gate transistors are formed in a triple P-well in a deep N-well, the programming biasing voltages are a positive program voltage level (approximately 10V+/−2V) applied to the control gate, a select gate voltage level (approximately 2V) applied to the gate of the select transistor, a drain/source program voltage level (approximately −8V+/−2V) applied to the drain of the select gate transistor and the source of the bottommost of the serially connected charge retaining transistors, the negative triple well program voltage level (approximately −8V+/−2V) applied to the triple P-well, and a well biasing voltage level that is the voltage level of the power supply voltage source (VDD) applied to the deep N-well. The erase biasing voltages are a positive select voltage level to the gate of the select transistor and a negative erase voltage level (approximately −10V+/−2V) applied to the control gate and a positive well erase voltage level (approximately 8V+/−2V) applied to the triple P-well and the deep N-well and coupled to the drain/source and source/drain of the serially connected charge retaining transistors. During erasing, the select gate is set to the well erase voltage level (approximately 8V+/−2V) to prevent stress in the gate oxide of the select transistor.

In still other embodiments of the nonvolatile memory device, where each of the flash memory cells are a NAND or NOR flash memory cell and the serially connected charge retaining transistors are N-channel SONOS charge trapping transistors formed in a triple P-well in a deep N-well, the programming biasing voltages are a positive program voltage level (approximately 7V+/−1V) applied to the control gate, select voltage level (approximately 2V) applied to the gate of the select transistor, a negative drain/source program voltage level (−5V+/−1V) applied to the drain/source and source/drain of the serially connected charge retaining transistors and to the triple P-well, and a deep well biasing voltage level that is the voltage level of the power supply voltage source (VDD) applied to the deep N-well. The erasing biasing voltages are a negative erase voltage level (approximately −7V+/−1V) applied to the control gate, a positive well erase voltage level (approximately 5V+/−1V) applied to the triple P-well and to the deep N-well and coupled to the drains and sources of the select transistor and the serially connected charge retaining transistors. During erasing, the select gate is set to the biasing erase voltage level (approximately 5V+/−1V) to prevent stress in the gate oxide of the select transistor.

In other embodiments of the nonvolatile memory device, where each of the flash memory cells are a NAND or NOR flash memory cell and the serially connected charge retaining transistors are P-channel floating gate transistors formed in or in a triple N-well in a deep P-well, the programming biasing voltages are a negative program voltage level (−10V+/−2V) applied to the control gate, a select voltage level (approximately −2V) applied to the gate of the select transistor, a positive drain/source program voltage level (8V+/−2V) applied to the drain of the select transistor and the source of the bottommost of the serially connected charge retaining transistors, and a well biasing voltage level (approximately 8V+/−2V) applied to the triple N-well, and a well biasing voltage level that is the voltage level of the ground (0V) applied to the deep P-well. The erasing biasing voltages are a positive erase voltage level (approximately 10V+/−2V) applied to the control gate, and a negative well biasing erase voltage level (approximately −8V+/−2V) applied to the triple N-well and to the deep P-well and coupled to the drain of the select transistor and the drains and sources of the serially connected charge retaining transistors. During erasing, the select gate is set to the well biasing erase voltage level (approximately −8V+/−2V) to prevent stress in the gate oxide of the select transistor.

In other embodiments of the nonvolatile memory device, where each of the flash memory cells are a NAND or NOR flash memory cell and the serially connected charge retaining transistors are P-channel SONOS charge trapping transistors formed in a triple N-well in deep P-well, the programming biasing voltages are a negative program voltage level (approximately −7V+/−1V) applied to the control gate, gate select voltage level (approximately −2V) to the gate of the select transistor, a positive drain/source program voltage level (5V+/−1V) applied to the drain of the select transistor and source of the bottommost charge retaining transistor of the serially connected charge retaining transistors, and a well biasing voltage level (approximately 5V+/−1V) applied to the triple N-well, and a well biasing voltage level that is the voltage level of the ground (0V) applied to the deep P-well. The erasing biasing voltages are a positive erase voltage level (approximately 7V+/−1V) applied to the control gate and a negative erase well biasing voltage level (approximately −5V+/−1V) applied to the triple N-well and to the deep P-well and coupled to the drain/source and source/drain of the serially connected charge retaining transistors. During erasing, the select gate is set to the well biasing erase voltage level (approximately −5V+/−1V) to prevent stress in the gate oxide of the select transistor.

In some embodiments of the nonvolatile memory device, where each of the flash memory cells are a NOR flash memory cell and the serially connected charge retaining transistors are N-channel floating gate transistors are formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −10V+/−2V) applied to the control gate, a select gate voltage level (approximately 7V) applied to the gate of the select transistor, a drain/source program voltage level (approximately 5V+/−2V) applied to the drain of the select gate transistor and the source of the bottommost of the serially connected charge retaining transistors, the ground voltage level (approximately 0V) applied to the triple P-well, and a well biasing voltage level that is the voltage level of the power supply voltage source (VDD) applied to the deep N-well. The erase biasing voltages are a positive select voltage level to the gate of the select transistor and a positive erase voltage level (approximately 10V+/−2V) applied to the control gate and a negative well erase voltage level (approximately −8V+/−2V) applied to the triple P-well and coupled to the drain/source and source/drain of the serially connected charge retaining transistors, and a power supply voltage (VDD) level is applied to the deep N-well. During erasing, the select gate is set to the well erase voltage level (approximately −8V+/−2V) to prevent stress in the gate oxide of the select transistor.

In still other embodiments of the nonvolatile memory device, where each of the flash memory cells are a NOR flash memory cell and the serially connected charge retaining transistors are N-channel SONOS charge trapping transistors formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −7V+/−1V) applied to the control gate, select voltage level (approximately 7V) applied to the gate of the select transistor, a drain/source program voltage level (5V+/−1V) applied to the drain/source and source/drain of the serially connected charge retaining transistors, a triple well biasing voltage (0V) applied to the triple P-well, and a deep well biasing voltage level that is the voltage level of the power supply voltage source (VDD) applied to the deep N-well. The erasing biasing voltages are a positive erase voltage level (approximately 7V+/−1V) applied to the control gate, a negative well biasing erase voltage level (approximately −5V+/−1V) applied to the triple P-well and coupled to the drains and sources of the select transistor and the serially connected charge retaining transistors, and a power supply voltage (VDD) level is applied to the deep N-well. During erasing, the select gate is set to the negative well biasing erase voltage level (approximately −5V+/−1V) to prevent stress in the gate oxide of the select transistor.

In other embodiments of the nonvolatile memory device, where each of the flash memory cells are a NOR flash memory cell and the serially connected charge retaining transistors are P-channel floating gate transistors formed in a single N-well, the threshold voltage levels representing erased serially connected charge retaining transistors and the threshold voltage level representing programmed serially connected charge retaining transistors are reversed. The programming biasing voltages are a positive program voltage level (10V+/−2V) applied to the control gate, a select voltage level (approximately −7V+/−2V) applied to the gate of the select transistor, a negative drain/source program voltage level (−5V+/−2V) applied to the drain of the select transistor and the source of the bottommost of the serially connected charge retaining transistors, and a well biasing power source voltage level applied to the N-well. The erasing biasing voltages are a negative erase voltage level (approximately −10V+/−2V) applied to the control gate, and a positive well biasing erase voltage level (approximately 8V+/−2V) applied to the N-well and coupled to the drain of the select transistor and the drains and sources of the serially connected charge retaining transistors. During erasing, the select gate is set to the well biasing erase voltage level (approximately 8V+/−2V) to prevent stress in the gate oxide of the select transistor.

In other embodiments of the nonvolatile memory device, where each of the flash memory cells are a NOR flash memory cell and the serially connected charge retaining transistors are P-channel SONOS charge trapping transistors formed in an N-well, the threshold voltage levels representing erased serially connected charge retaining transistors and the threshold voltage level representing programmed serially connected charge retaining transistors are reversed. The programming biasing voltages are a positive program voltage level (approximately 7V+/−1V) applied to the control gate, gate select voltage level (approximately −7V) to the gate of the select transistor, a negative drain/source program voltage level (−5V+/−1V) applied to the drain of the select transistor and source of the bottommost charge retaining transistor of the serially connected charge retaining transistors, and a well biasing power source voltage level (VDD) applied to the N-well. The erasing biasing voltages are a negative erase voltage level (approximately −7V+/−1V) applied to the control gate and a positive erase well biasing voltage level (approximately 5V+/−1V) applied to the N-well and coupled to the drain/source and source/drain of the serially connected charge retaining transistors. During erasing, the select gate is set to the well biasing erase voltage level (approximately 5V+/−1V) to prevent stress in the gate oxide of the select transistor.

In other embodiments, a method for forming a flash memory cell includes diffusing an impurity of a first conductivity type in a diffusion well of a second conductivity type to form drain/source regions for a select transistor serially connected with a string of at least one charge retaining transistors. In some embodiments of the method for forming a flash memory cell, the diffusion well is formed in the surface of a substrate of the first conductivity type. In other embodiments of the method for forming a flash memory cell, the diffusion well is formed in a deep diffusion well of the first conductivity type that is formed in the surface of a substrate of the second conductivity type.

A first of the drain/source regions is constructed as a drain for the select transistor. A second of the drain/source regions is constructed as a source of a bottom most of the at least one charge retaining transistors. A third of the drain/source regions is a source of the select transistor and the drain of a topmost of the at least one charge retaining transistors The drain/source regions are arranged to form the series connected string of the at least one charge retaining transistors. A thin oxide is formed over a bulk region between the source and drain regions of the select transistor serially and the at least one charge retaining transistors. A charge retaining layer is formed over the oxide layer and a gate oxide layer is formed over the charge retaining layer of each of the charge retaining transistors. A control gate is formed over the gate oxide of the at least one charge retaining transistors. The gate of the select transistor is similarly formed over the gate oxide.

The drain of the select transistor is connected to receive biasing voltages for programming, erasing, and reading the two series connected charge retaining transistors. Similarly, a source of the bottommost of the at least one charge retaining transistors is connected to receive biasing voltages for programming, erasing, and reading the two series connected charge retaining transistors. The drain/source regions between the drain of the topmost charge retaining transistor and the source of the bottommost charge retaining form the string of commonly connected at least one charge retaining transistors that are connected solely together. The drain/source regions are formed in a diffusion well. In some embodiments the diffusion well is formed in a deep diffusion well.

In various embodiments of the method for forming a flash memory cell, the flash memory cell is formed with the select transistor and a single charge retaining transistor to form a NOR flash memory cell. In other embodiments of the method for forming a flash memory cell, the flash memory cell is formed with the select transistor and two or more charge retaining transistors to form a NAND flash memory cell. In various embodiments of the method for forming a flash memory cell, the flash memory cell is formed with the select transistor and thirty-two charge retaining transistors to form a NAND flash memory cell.

The drain of the select transistor is connected to a local bit line and the source of a bottommost of the string of the at least one dual charge retaining transistors is connected to a local source line. The drain/sources of the commonly connected dual serially connected charge retaining transistors of the string of at least one charge retaining transistors are connected solely together.

In some embodiments of the method for forming a flash memory cell, the first conductivity type is formed by diffusing an N-type impurity and the second conductivity type is formed by diffusing a P-type impurity such that the select transistor and the string, of at least one charge retaining transistors are N-channel transistors. In some embodiments of the method for forming a flash memory cell, the first conductivity type is formed by diffusing an P-type impurity and the second conductivity type is formed by diffusing a N-type impurity such that the select transistor and the string of at least one charge retaining transistors are P-channel transistors. In still other embodiments of the method for forming a flash memory cell, the N-channel select transistor and the string of at least one charge retaining transistors are formed in a P-type well. In various embodiments of the method for forming a flash memory cell, the P-type well is formed in deep N-type well that is formed in a P-type substrate. In still other embodiments of the method for forming a flash memory cell, the P-channel select transistor and the string of at least one charge retaining transistors are formed in an N-type well. In various embodiments of the method for forming a flash memory cell, the N-type well is formed in deep P-type well that is formed in an N-type substrate. In various embodiments of the method for forming a flash memory cell, the N-type well is formed in a P-type substrate.

In various embodiments of the method for forming a flash memory cell, the string of at least one charge retaining transistors each have a charge retaining layer that is formed of a charge storing polycrystalline floating gate layer or a metal layer. In some embodiments of the method for forming a flash memory cell, the select transistor is formed of a floating gate charge retaining transistor where the floating gate and the control gate are shorted. In other embodiments of the method for forming a flash memory cell, the string of at least one charge retaining transistors each have a charge retaining layer that is formed of a charge trapping insulating layer where the charge trapping insulating layer is a silicon nitride forming a silicon oxide nitride oxide silicon (SONOS) structure.

In various embodiments of the method for forming a flash memory cell, the local bit line connected to the drain of the select transistor and the local source line connected to the source of the bottommost charge retaining transistor of the string of at least one charge retaining transistors are parallel with each other and are parallel to an associated column of flash memory cells within an array of the flash memory cells. In some embodiments of the method for forming a flash memory cell, the local bit lines and local source lines are formed of metal conductors formed on the surface of the substrate above the associated column of flash memory cells.

In various embodiments of a method for operating a flash memory cell, programming and erasing biasing voltages are applied to a control gate, a drain or source, and a bulk region of a string of at least one charge retaining transistors to inject charge to or from the charge retaining layer to selectively program or erase the selected charge retaining transistor(s) of the string of at least one charge retaining transistors. The program and erase voltage levels are selected to have a magnitude less than the source-to-drain breakdown voltage of transistors of the peripheral circuitry that generates and distributes the program and erase biasing voltages. The programming voltages that are applied to the sources an drains of the selected charge retaining transistors are essentially equal to prevent punch through during programming. In some embodiments of a method for operating a flash memory cell, the selected charge retaining transistor of the string of at least one charge retaining transistors is programmed and erased by a Fowler-Nordheim tunneling. In various embodiments of a method for operating a flash memory cell, the Fowler-Nordheim tunneling is through a channel region between the drain and source of the selected charge retaining transistor. In various embodiments, the Fowler-Nordheim tunneling is through an edge of a drain and/or source of the selected charge retaining transistor. In assorted embodiments of a method for operating a flash memory cell, the threshold voltage levels of the charge retaining transistors have a positive magnitude for a programmed state and a negative magnitude of an erased state. In some embodiments of a method for operating a flash memory cell of a method for operating a flash memory cell, where the charge retaining transistors have charge retaining transistors have the positive magnitude for a programmed state and the negative magnitude of an erased state, the charge retaining transistors are N-channel charge retaining transistors. In other embodiments of a method for operating a flash memory cell, the threshold voltage levels of the charge retaining transistors have a negative magnitude for a programmed state and a positive magnitude for an erased state. In some embodiments of a method for operating a flash memory cell, where the charge retaining transistors have charge retaining transistors have the negative magnitude for a programmed state and the positive magnitude of an erased state, the charge retaining transistors are P-channel charge retaining transistors.

In some embodiments of a method for operating a flash memory cell, where each of the flash memory cells are a NAND or NOR flash memory cell and the serially connected charge retaining transistors are N-channel floating gate transistors are formed in a triple P-well in a deep N-well, the programming biasing voltages are a positive program voltage level (approximately 10V+/−2V) applied to the control gate, a select gate voltage level (approximately 2V) applied to the gate of the select transistor, a drain/source program voltage level (approximately −8V+/−2V) applied to the drain of the select gate transistor and the source of the bottommost of the serially connected charge retaining transistors, the negative triple well program voltage level (approximately −8V+/−2V) applied to the triple P-well, and a well biasing voltage level that is the voltage level of the power supply voltage source (VDD) applied to the deep N-well. The erase biasing voltages are a positive select voltage level to the gate of the select transistor and a negative erase voltage level (approximately −10V+/−2V) applied to the control gate and a positive well erase voltage level (approximately 8V+/−2V) applied to the triple P-well and the deep N-well and coupled to the drain/source and source/drain of the serially connected charge retaining transistors. During erasing, the select gate is set to the well erase voltage level (approximately 8V+/−2V) to prevent stress in the gate oxide of the select transistor.

In still other embodiments of a method for operating a flash memory cell, where each of the flash memory cells are a NAND or NOR flash memory cell and the serially connected charge retaining transistors are N-channel SONOS charge trapping transistors formed in a triple P-well in a deep N-well, the programming biasing voltages are a positive program voltage level (approximately 7V+/−1V) applied to the control gate, select voltage level (approximately 2V) applied to the gate of the select transistor, a negative drain/source program voltage level (−5V+/−1V) applied to the drain/source and source/drain of the serially connected charge retaining transistors and to the triple P-well, and a deep well biasing voltage level that is the voltage level of the power supply voltage source (VDD) applied to the deep N-well. The erasing biasing voltages are a negative erase voltage level (approximately −7V+/−1V) applied to the control gate, a positive well erase voltage level (approximately 5V+/−1V) applied to the triple P-well and to the deep N-well and coupled to the drains and sources of the select transistor and the serially connected charge retaining transistors. During erasing, the select gate is set to the biasing erase voltage level (approximately 5V+/−1V) to prevent stress in the gate oxide of the select transistor.

In other embodiments of a method for operating a flash memory cell, where each of the flash memory cells are a NAND or NOR flash memory cell and the serially connected charge retaining transistors are P-channel floating gate transistors formed in a triple N-well in a deep P-well, the programming biasing voltages are a negative program voltage level (−10V+/−2V) applied to the control gate, a select voltage level (approximately −2V) applied to the gate of the select transistor, a positive drain/source program voltage level (8V+/−2V) applied to the drain of the select transistor and the source of the bottommost of the serially connected charge retaining transistors, and a well biasing voltage level (approximately 8V+/−2V) applied to the triple N-well, and a well biasing voltage level that is the voltage level of the ground (0V) applied to the deep P-well. The erasing biasing voltages are a positive erase voltage level (approximately 10V+/−2V) applied to the control gate, and a negative well biasing erase voltage level (approximately −8V+/−2V) applied to the triple N-well and to the deep P-well and coupled to the drain of the select transistor and the drains and sources of the serially connected charge retaining transistors. During erasing, the select gate is set to the well biasing erase voltage level (approximately −8V+/−2V) to prevent stress in the gate oxide of the select transistor.

In other embodiments of a method for operating a flash memory cell, where each of the flash memory cells are a NAND or NOR flash memory cell and the serially connected charge retaining transistors are P-channel SONOS charge trapping transistors formed in a triple N-well in deep P-well, the programming biasing voltages are a negative program voltage level (approximately −7V+/−1V) applied to the control gate, gate select voltage level (approximately −2V) to the gate of the select transistor, a positive drain/source program voltage level (5V+/−1V) applied to the drain of the select transistor and source of the bottommost charge retaining transistor of the serially connected charge retaining transistors, and a well biasing voltage level (approximately 5V+/−1V) applied to the triple N-well, and a well biasing voltage level that is the voltage level of the ground (0V) applied to the deep P-well. The erasing biasing voltages are a positive erase voltage level (approximately 7V+/−1V) applied to the control gate and a negative erase well biasing voltage level (approximately −5V+/−1V) applied to the triple N-well and to the deep P-well and coupled to the drain/source and source/drain of the serially connected charge retaining transistors. During erasing, the select gate is set to the well biasing erase voltage level (approximately −5V+/−1V) to prevent stress in the gate oxide of the select transistor.

In some embodiments of a method for operating a flash memory cell, where each of the flash memory cells are a NOR flash memory cell and the serially connected charge retaining transistors are N-channel floating gate transistors are formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −10V+/−2V) applied to the control gate, a select gate voltage level (approximately 7V) applied to the gate of the select transistor, a drain/source program voltage level (approximately 5V+/−2V) applied to the drain of the select gate transistor and the source of the bottommost of the serially connected charge retaining transistors, the ground voltage level (approximately 0V) applied to the triple P-well, and a well biasing voltage level that is the voltage level of the power supply voltage source (VDD) applied to the deep N-well. The erase biasing voltages are a positive select voltage level to the gate of the select transistor and a positive erase voltage level (approximately 10V+/−2V) applied to the control gate and a negative well erase voltage level (approximately −8V+/−2V) applied to the triple P-well and coupled to the drain/source and source/drain of the serially connected charge retaining transistors, and a power supply voltage (VDD) level is applied to the deep N-well. During erasing, the select gate is set to the well erase voltage level (approximately −8V+/−2V) to prevent stress in the gate oxide of the select transistor.

In still other embodiments of a method for operating a flash memory cell, where each of the flash memory cells are NOR flash memory cell and the serially connected charge retaining transistors are N-channel SONOS charge trapping transistors formed in a triple P-well in a deep N-well, the threshold voltage levels representing erased serially connected charge retaining transistors and the threshold voltage level representing programmed serially connected charge retaining transistors are reversed. The programming biasing voltages are a negative program voltage level (approximately −7V+/−1V) applied to the control gate, select voltage level (approximately 7V) applied to the gate of the select transistor, a drain/source program voltage level (5V+/−1V) applied to the drain/source and source/drain of the serially connected charge retaining transistors, a triple well biasing voltage (0V) applied to the triple P-well, and a deep well biasing voltage level that is the voltage level of the power supply voltage source (VDD) applied to the deep N-well. The erasing biasing voltages are a positive erase voltage level (approximately 7V+/−1V) applied to the control gate, a negative well biasing erase voltage level (approximately −5V+/−1V) applied to the triple P-well and coupled to the drains and sources of the select transistor and the serially connected charge retaining transistors, and a power supply voltage (VDD) level is applied to the deep N-well. During erasing, the select gate is set to the negative well biasing erase voltage level (approximately −5V+/−1V) to prevent stress in the gate oxide of the select transistor.

In other embodiments of a method for operating a flash memory cell, where each of the flash memory cells are a NOR flash memory cell and the serially connected charge retaining transistors are P-channel floating gate transistors formed in a single N-well, the threshold voltage levels representing erased serially connected charge retaining transistors and the threshold voltage level representing programmed serially connected charge retaining transistors are reversed. The programming biasing voltages are a positive program voltage level (10V+/−2V) applied to the control gate, a select voltage level (approximately −7V+/−2V) applied to the gate of the select transistor, a negative drain/source program voltage level (−5V+/−2V) applied to the drain of the select transistor and the source of the bottommost of the serially connected charge retaining transistors, and a well biasing power source voltage level (VDD) applied to the N-well. The erasing biasing voltages are a negative erase voltage level (approximately −10V+/−2V) applied to the control gate, and a positive well biasing erase voltage level (approximately 8V+/−2V) applied to the N-well and coupled to the drain of the select transistor and the drains and sources of the serially connected charge retaining transistors. During erasing, the select gate is set to the well biasing erase voltage level (approximately 8V+/−2V) to prevent stress in the gate oxide of the select transistor.

In other embodiments of a method for operating a flash memory cell, where each of the flash memory cells are a NOR flash memory cell and the serially connected charge retaining transistors are P-channel SONOS charge trapping transistors formed in an N-well, the threshold voltage levels representing erased serially connected charge retaining transistors and the threshold voltage level representing programmed serially connected charge retaining transistors are reversed. The programming biasing voltages are a positive program voltage level (approximately 7V+/−1V) applied to the control gate, gate select voltage level (approximately −7V) to the gate of the select transistor, a negative drain/source program voltage level (−5V+/−1V) applied to the drain of the select transistor and source of the bottommost charge retaining transistor of the serially connected charge retaining transistors, and a well biasing power source voltage level (VDD) applied to the N-well. The erasing biasing voltages are a negative erase voltage level (approximately −7V+/−1V) applied to the control gate and a positive erase well biasing voltage level (approximately 5V+/−1V) applied to the N-well and coupled to the drain/source and source/drain of the serially connected charge retaining transistors. During erasing, the select gate is set to the well biasing erase voltage level (approximately 5V+/−1V) to prevent stress in the gate oxide of the select transistor.

### BRIEF DESCRIPTION OF THE DRAWINGS

FIG. 1a is a cross sectional view of a multiple transistor string configured as a NAND floating gate flash nonvolatile memory cell in a triple well structure embodying the principles of this invention.

FIG. 1b is a cross sectional view of an multiple-transistor string configured as NOR floating gate flash nonvolatile memory cells in a single well structure embodying the principles of this invention.

FIG. 1c is a cross sectional view of a multiple-transistor string configured as a NAND SONOS charge trapping flash nonvolatile memory cell in a triple well structure embodying the principles of this invention.

FIG. 1d is a cross sectional view of a multiple-transistor string configured as NOR SONOS charge trapping flash nonvolatile memory cells in a single well structure embodying the principles of this invention.

FIG. 2a is a schematic of a floating gate NAND flash nonvolatile memory cell embodying the principles of this invention.

FIG. 2b is a schematic of a SONOS charge trapping NAND flash nonvolatile memory cell embodying the principles of this invention.

FIG. 3a is a schematic of a floating gate NOR nonvolatile flash memory cell embodying the principles of this invention.

FIG. 3b is schematic of a SONOS charge trapping NOR flash nonvolatile memory cell embodying the principles of this invention.

FIG. 4a is a schematic of a floating gate NAND flash nonvolatile memory device embodying the principles of this invention.

FIG. 4b is a schematic of a SONOS charge trapping NAND flash nonvolatile memory device embodying the principles of this invention.

FIG. 4c is a schematic of a floating gate NOR flash nonvolatile memory device embodying the principles of this invention.

FIG. 4d is a schematic of a SONOS charge trapping NOR flash nonvolatile memory device embodying the principles of this invention.

FIG. 5 is a schematic diagram of a row voltage control circuit of the flash nonvolatile memory device of FIGS. 4a-4d embodying the principles of the present invention.

FIG. 6 is a schematic diagram of a column voltage control circuit of the flash nonvolatile memory device of FIGS. 4a-4d embodying the principles of the present invention.

FIG. 7 is a graph of threshold voltage levels for various embodiments of an N-channel transistor floating gate and SONOS charge trapping NAND and NOR flash memory cell embodying the principles of the present invention.

FIG. 8 is a table illustrating the voltage conditions for operating an array of an array of N-channel floating gate and SONOS charge trapping transistor NAND or NOR flash memory cells for reading, erasing, programming, and selected dual charge retaining NOR flash memory cells embodying the principles of the present invention.

FIG. 9 is a graph of threshold voltage levels for various embodiments of a P-channel transistor floating gate and SONOS charge trapping NAND and NOR flash memory cell embodying the principles of the present invention.

FIG. 10 is a table illustrating the voltage conditions for operating an array of an array of P-channel floating gate and SONOS charge trapping transistor NAND or NOR flash memory cells for reading, erasing, programming, and selected dual charge retaining NOR flash memory cells embodying the principles of the present invention.

FIG. 11 is a graph of threshold voltage levels for various embodiments of an N-channel transistor SONOS charge trapping NOR flash memory cell embodying the principles of the present invention.

FIG. 12 is a table illustrating the voltage conditions for operating an array of an array of N-channel SONOS charge trapping transistor NOR flash memory cells for reading, erasing, programming, and selected dual charge retaining NOR flash memory cells embodying the principles of the present invention.

FIG. 13 is a graph of threshold voltage levels for various embodiments of a P-channel transistor floating gate and SONOS charge trapping NOR flash memory cell embodying the principles of the present invention.

FIG. 14 is a table illustrating the voltage conditions for operating an array of an array of P-channel floating gate and SONOS charge trapping transistor NOR flash memory cells for reading, erasing, programming, and selected dual charge retaining NOR flash memory cells embodying the principles of the present invention.

FIG. 15 is a flow chart of an erase operation for various embodiments of a floating gate and SONOS charge trapping NAND and NOR flash memory cells embodying the principles of the present invention.

FIG. 16 is a flow chart of a read operation for various embodiments of a floating gate and SONOS charge trapping NAND and NOR flash memory cells embodying the principles of the present invention.

FIG. 17 is a flow chart of a program operation for various embodiments of a floating gate and SONOS charge trapping NAND and NOR flash memory cells embodying the principles of the present invention.

### DETAILED DESCRIPTION OF THE INVENTION

A charge retaining (floating gate or SONOS charge trapping) transistor flash nonvolatile memory cell is formed of a select transistor serially connected with a string of at least one charge retaining transistors. In some embodiments, the flash memory cell has the select transistor and a single charge retaining transistor to form a NOR flash memory cell. In other embodiments, the flash memory cell has the select transistor and two or more charge retaining transistors to form a NAND flash memory cell. The select transistor and the charge retaining transistors may be N-channel or a P-channel charge retaining (floating gate or SONOS charge trapping) transistors. In an array of charge retaining transistor flash nonvolatile memory cells, a bit line and a source line are arranged to be in parallel with each column of the flash nonvolatile memory cells. A method of operating an array of charge retaining transistor flash NAND or NOR flash nonvolatile memory cells biases the bit lines and source lines to approximately equal programming voltage levels to be distributed to the sources and drains of the charge retaining transistors to prevent drain-to-source punch through. Further, in some embodiments, the method of operating an array of NAND or NOR charge retaining transistor flash nonvolatile memory cells provides program voltage levels applied to a control gate of a selected charge retaining transistors and to a bulk region of the charge retaining transistors have a magnitude less than a breakdown voltage of transistors forming peripheral circuits generating and distributing the program voltage levels.

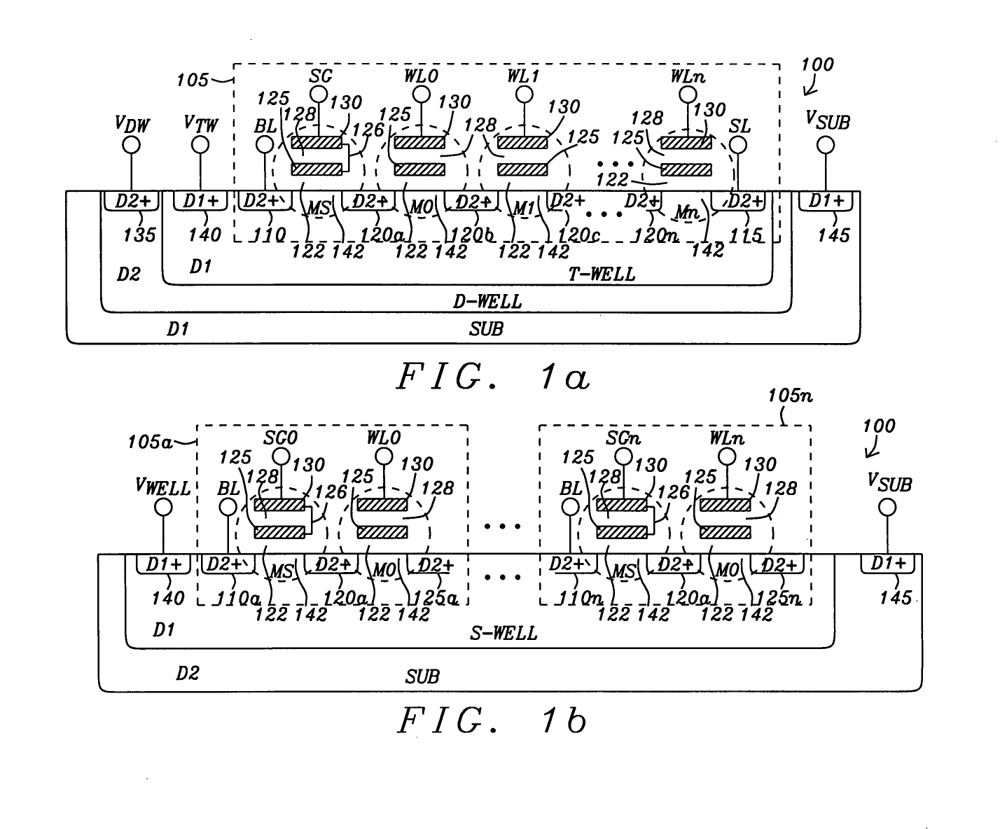

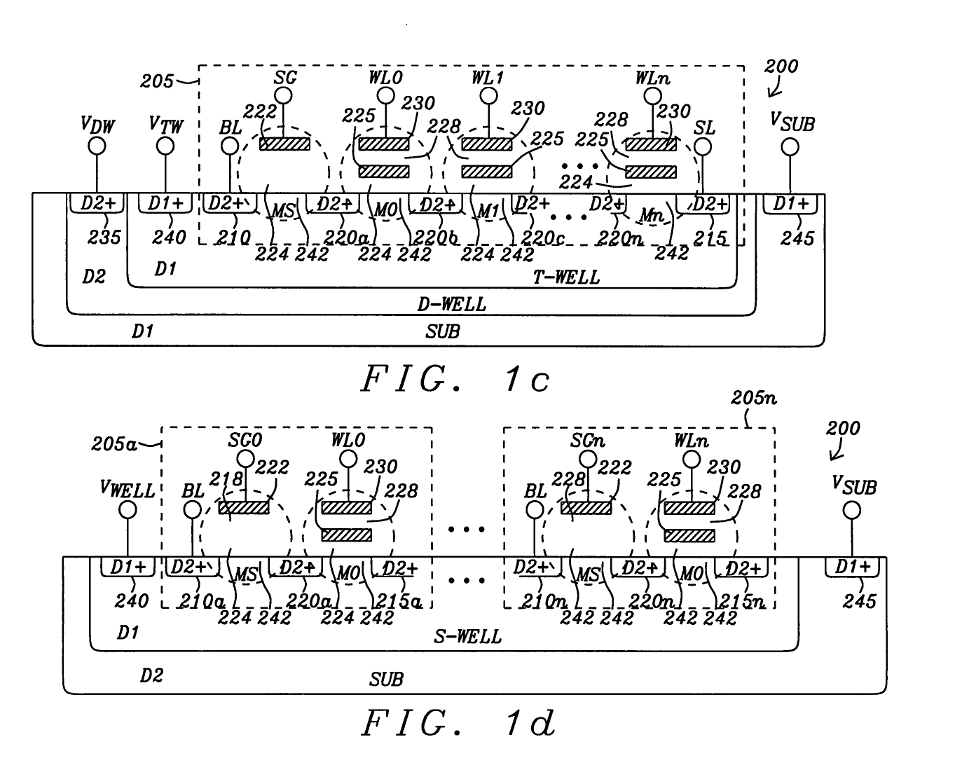

FIG. 1a is a cross sectional view of a multiple transistor string configured as a NAND floating gate flash nonvolatile memory cell 100 in a triple well structure T-WELL. FIG. 1b is a cross sectional view of a multiple-transistor configured as NOR floating gate flash nonvolatile memory cells 100 in a single well structure. Refer to FIG. 1a for a discussion of a triple well construction of a flash memory cell 105. A substrate SUB of first conductivity type D1 has a deep well D-WELL of a diffusion of a second conductivity type D2 implanted into its surface. A triple well of the first conductivity type D1 is implanted into the surface of the deep well D-WELL. The flash nonvolatile memory cell 105 is formed within the triple well T-WELL. The source/drain regions 110, 115, 120a, 120b, . . . , 120n of the second conductivity type D2 are implanted into the surface of the triple well T-WELL. The source/drain region 110 is the drain of the select transistor MS. The source/drain region 120a is the source of the select transistor MS and the drain of the topmost charge retaining transistor M0. The source/drain regions 120b, . . . , 120n are the sources and drains of the serially connected charge retaining transistors M0, M1, . . . , Mn. The source/drain region 115 is the source of the bottommost charge retaining transistor Mn.

A thin oxide 122 is placed over a channel region 142 between the source/drain regions 110, 115, 120a, 120b, . . . , 120n of the select transistor MS and each of the charge retaining transistors M0, M1, . . . , Mn. The thin oxide 122 that is a feature of the charge retaining transistors M0, M1, . . . , Mn is the tunneling oxide. In the embodiment as shown, a first polycrystalline silicon layer 125 is formed over the thin oxide 122 to form the floating gate of the charge retaining transistors M0, M1, . . . , Mn. An interlayer oxide 128 is formed over the first polycrystalline silicon layer 125 and a second poly crystalline layer 130 is formed over the interlayer oxide 128 to form the control gates of the charge retaining transistors M0, M1, . . . , Mn. The control gates of the charge retaining transistors M0, M1, . . . , Mn are connected to word lines WL0, WL1, . . . , WLn to receive the biasing voltage levels for programming, erasing, and reading the charge retaining transistors M0, M1, . . . , Mn.

The first polycrystalline silicon layer 125 of the select transistor MS is electrically connected 126 or shorted to the second poly crystalline layer 130 to form the control gate of the select transistor MS. In some embodiments, an opening is formed in the interlayer oxide 128 to create the electrical connection 126. The control gate (the shorted first and second polycrystalline silicon layers 125 and 130) of the select transistor MS is connected to the select gate SG. The select gate SG provides the control signals for activating and deactivating the select transistor MS during programming, erasing, and reading.

The source 115 of the bottommost charge retaining transistor Mn is connected to the source line SL. The drain 110 of the select transistor MS is connected to the bit line BL. The source line SL and the bit line BL provide the biasing voltage levels to the sources and drains of the charge retaining transistors M0, M1, . . . , Mn for programming, erasing, and reading. In programming the charge retaining transistors M0, M1, . . . , Mn, the sources and drains 120a, 120b, . . . , 120n are set to a drain/source programming voltage level that is approximately equal such that the drain-to-source voltage is less than the drain-to-source breakdown voltage level BV_{DS}. By keeping the drain/source programming voltage level applied to the drains and sources 120a, 120b, . . . , 120n of the selected charge retaining transistors M0, M1, . . . , Mn, the gate length or the distance of the channel 142 between the drains and sources 120a, 120b, . . . , 120n of the charge retaining transistors M0, M1, . . . , Mn is now determined by the minimum feature size (λ) of the technology in which the flash nonvolatile memory cell 105 is implemented.

A contact region 145 of the first conductivity type D1 connects the substrate SUB to a substrate biasing voltage generator V_{SUB}. A contact region 135 of the second conductivity type D2 connects the deep well D-WELL to the deep well biasing voltage generator V_{DW}. A contact region 140 of the first conductivity type D1 connects the triple well T-WELL to the triple well biasing generator V_{TW}. The substrate biasing voltage generator V_{SUB}, the deep well biasing voltage generator V_{DW}%, and the triple well biasing generator V_{TW} provide necessary biasing voltages for programming, erasing, and reading the flash nonvolatile memory 105.

Refer now to FIG. 1b for a discussion of a single well construction of flash nonvolatile memory cells 105a, . . . , 105n. The structure of the select transistor MS and the charge retaining transistors M0 are fundamentally identical to that as described in FIG. 1a. In the NOR configuration, each of the memory cells 105a, . . . , 105n consists of select transistor MS and a charge retaining transistor M0. The source/drain regions 110a, . . . , 110n, 115a, . . . , 115n, 120a, . . . , 120n of the second conductivity type D2 are implanted into the surface of the single well S-WELL. The source/drain region 110a, . . . , 110n are the drains of the select transistors MS. The source/drain regions 120a, . . . , 120n are the sources of the select transistor MS and the drains of the charge retaining transistor M0. The source/drain region 115a, . . . , 115n are the sources of the charge retaining transistor M0.

A thin oxide 122 is placed over a channel region 142 between the source/drain regions 110a, . . . , 110n, 115a, . . . , 115n, 120a, . . . , 120n of the select transistors MS and each of the charge retaining transistors M0. The thin oxide 122 that is a feature of the charge retaining transistors M0 is the tunneling oxide. In the embodiment as shown, a first polycrystalline silicon layer 125 is formed over the thin oxide 122 to form the floating gate of the charge retaining transistors M0. An interlayer oxide 128 is formed over the first polycrystalline silicon layer 125 and a second poly crystalline layer 130 is formed over the interlayer oxide 128 to form the control gates of the charge retaining transistors M0. The control gates of the charge retaining transistors M0 are connected to word lines WL0, . . . , WLn to receive the biasing voltage levels for programming, erasing, and reading the charge retaining transistors M0.

The first polycrystalline silicon layer 125 of the select transistors MS is electrically connected 126 or shorted to the second poly crystalline layer 130 to form the control gate of the select transistors MS. In some embodiments, an opening is formed in the interlayer oxide 128 to create the electrical connection 126. The control gate (the shorted first and second polycrystalline silicon layers 125 and 130) of the select transistors MS is connected to the select gate SG. The select gate SG provides the control signals for activating and deactivating the select transistor MS during programming, erasing, and reading.

The sources 115a, . . . , 115n of the charge retaining transistors M0 are connected to the source line SL. The drains 110a, . . . , 110n of the select transistors MS are connected to the bit line BL. The source line SL and the bit line BL provide the biasing voltage levels to the sources and drains of the charge retaining transistors M0, M1, . . . , Mn for programming, erasing, and reading. In programming the charge retaining transistors M0, the sources 115a, . . . , 115n and drains 120a, . . . , 120n are set to a drain/source programming voltage level that is approximately equal such that the drain-to-source voltage is less than the drain-to-source breakdown voltage level BV_{DS}.

By keeping the drain/source programming voltage level applied to the sources 115a, . . . , 115n and drains 120a, . . . , 120n of the selected charge retaining transistors M0, the gate length or the distance of the channel 142 between the sources 115a, . . . , 115n and drains 120a, . . . , 120n of the charge retaining transistors M0 is now determined by the minimum feature size (λ) of the technology in which the flash nonvolatile memory cell 105 is implemented.

A contact region 145 of the first conductivity type D1 connects the substrate SUB to a substrate biasing voltage generator V_{SUB}. A contact region 140 of the first conductivity type D1 connects the single well S-WELL to the single well biasing generator V_{SW}. The substrate biasing voltage generator V_{SUB}, the deep well biasing voltage generator V_{DW}, and the single well biasing generator V_{SW} provide necessary biasing voltages for programming, erasing, and reading the flash nonvolatile memory 105.

The diffusion well S-well is formed of a diffusion of the second conductivity type D2 that is implanted into the substrate SUB of the first conductivity type D1. The flash nonvolatile memory cells 105 of FIGS. 1a and 1b are floating gate where the select transistors MS are formed with the same structure as the charge retaining transistors M0.

When the diffusions of the first conductivity type D1 are implanted with P-type impurities and the diffusions of the second conductivity type are implanted with N-type impurities, the select transistor MS and the charge retaining transistors M0 are referred to as N-channel transistors. When the diffusions of the first conductivity type D1 are implanted with N-type impurities and the diffusions of the second conductivity type are implanted with P-type impurities, the select transistor MS and the charge retaining transistors M0 are referred to as P-channel transistors.

FIG. 1c is a cross sectional view of a multiple transistor string configured as a NAND SONOS charge trapping flash nonvolatile memory cell 200 in a triple well structure T-WELL. FIG. 1d is a cross sectional view of a multiple-transistor string configured as NOR SONOS charge trapping flash nonvolatile memory cell 200 in a single well structure S-WELL. Referring to FIG. 1c, the triple well structure T-WELL is as described in FIG. 1a with a substrate SUB having a deep well diffusion D-WELL of a second conductivity type D2 implanted into its surface. A triple well T-WELL of the first conductivity type D1 is implanted into the surface of the deep well D-WELL. The flash nonvolatile memory cell 205 is formed within the triple well T-WELL. The source/drain regions 210, 215, 220a, 220b, . . . , 220n of the second conductivity type D2 are implanted into the surface of the triple well T-WELL. The source/drain region 210 is the drain of the select transistor MS. The source/drain region 220a is the source of the select transistor MS and the drain of the topmost charge retaining transistor M0. The source/drain regions 220b, . . . , 220n are the source and drains of the serially connected charge retaining transistors M0, M1, . . . , Mn. The source/drain region 215 is the source of the bottommost charge retaining transistor Mn.

A thin oxide 224 is placed over a channel region 242 between the source/drain regions 210, 215, 220a, 220b, . . . , 220n of the select transistor MS and each of the charge retaining transistors M0, M1, . . . , Mn. The thin oxide 222 that is a feature of the charge retaining transistors M0, M1, . . . , Mn is the tunneling oxide. In the embodiment as shown, a silicon nitride (SiNx) layer 225 is formed over the thin oxide 224 to form a charge trapping layer of the charge retaining transistors M0, M1, . . . , Mn. An interlayer oxide 228 is formed over the silicon nitride (SiNx) layer 225 and a poly crystalline layer 230 is formed over the interlayer oxide 228 to form the control gates of the charge retaining transistors M0, M1, . . . , Mn. The control gates of the charge retaining transistors M0, M1, . . . , Mn are connected to word lines WL0, WL1, . . . , WLm to receive the biasing voltage levels for programming, erasing, and reading the charge retaining transistors M0, M1, . . . , Mn.

A polycrystalline silicon layer 222 is formed over the thin oxide 224 of the select transistor MS to form the control gate of the select transistor MS. The control gate 222 of the select transistor MS is connected to the select gate SG. The select gate SG provides the control signals for activating and deactivating the select transistor MS during programming, erasing, and reading.

The source 215 of the bottommost charge retaining transistor Mn is connected to the source line SL. The drain 210 of the select transistor MS is connected to the bit line BL. The source line SL and the bit line BL provide the biasing voltage levels to the sources and drains of the charge retaining transistors M0, M1, . . . , Mn for programming, erasing, and reading. In programming the charge retaining transistors M0, M1, . . . , Mn, the sources and drains 220a, 220b, . . . , 220n are set to a drain/source programming voltage level that is approximately equal such that the drain-to-source voltage is less than the drain-to-source breakdown voltage level BV_{DS}. By keeping the drain/source programming voltage level applied to the drains and sources 220a, 220b, . . . , 220n of the selected charge retaining transistors M0, M1, . . . , Mn, the gate length or the distance of the channel 242 between the drains and sources 220a, 220b, . . . , 220n of the charge retaining transistors M0, M1, . . . , Mn is now determined by the minimum feature size (λ) of the technology in which the flash nonvolatile memory cell 205 is implemented.

A contact region 245 of the first conductivity type D1 connects the substrate SUB to a substrate biasing voltage generator V_{SUB}. A contact region 235 of the second conductivity type D2 connects the deep well D-WELL to the deep well biasing voltage generator V_{DW}. A contact region 240 of the first conductivity type D1 connects the triple well T-WELL to the triple well biasing generator V_{TW}. The substrate biasing voltage generator V_{SUB}, the deep well biasing voltage generator V_{DW}, and the triple well biasing generator V_{TW}, provide necessary biasing voltages for programming, erasing, and reading the flash nonvolatile memory 205.

When the diffusions of the first conductivity type D1 are implanted with P-type impurities and the diffusions of the second conductivity type are implanted with N-type impurities, the select transistor MS and the charge retaining transistors M0, M1, . . . , Mn are referred to as N-channel transistors. When the diffusions of the first conductivity type D1 are implanted with N-type impurities and the diffusions of the second conductivity type are implanted with P-type impurities, the select transistor MS and the charge retaining transistors M0, M1, . . . , Mn are referred to as P-channel transistors.

Refer now to FIG. 1d for a discussion of a single well construction of NOR flash nonvolatile memory cells 205a, . . . , 205n. The structure of the select transistor MS and the charge retaining transistors M0 is identical to that as described in FIG. 1c. In the NOR configuration, each of the memory cells 205a, . . . , 205n consists of select transistor MS and a charge retaining transistor M0 as described in FIG. 1b. The source/drain regions 210a, . . . , 210n, 215a, . . . , 215n, 220a, . . . , 220n of the second conductivity type D2 are implanted into the surface of the single well S-WELL. The source/drain region 210a, . . . , 210n are the drains of the select transistors MS. The source/drain regions 220a, . . . , 220n are the sources of the select transistor MS and the drains of the charge retaining transistor M0. The source/drain region 215a, . . . , 215n are the sources of the charge retaining transistor M0.

A thin oxide 222 is placed over a channel region 242 between the source/drain regions 210a, . . . , 210n, 215a, . . . , 215n, 220a, . . . , 220n of the select transistors MS and each of the charge retaining transistors M0. The thin oxide 222 that is a feature of the charge retaining transistors M0 is the tunneling oxide. In the embodiment as shown, a first polycrystalline silicon layer 225 is formed over the thin oxide 222 to form the floating gate of the charge retaining transistors M0. An interlayer oxide 228 is formed over the first polycrystalline silicon layer 225 and a second poly crystalline layer 230 is formed over the interlayer oxide 228 to form the control gates of the charge retaining transistors M0. The control gates of the charge retaining transistors M0 are connected to word lines WL0, . . . , WLn to receive the biasing voltage levels for programming, erasing, and reading the charge retaining transistors M0.

The first polycrystalline silicon layer for the select transistors MS is eliminated and the second poly crystalline layer 222 forms the control gate of the select transistors MS. The control gate of the select transistors MS is connected to the select gate SG. The select gate SG provides the control signals for activating and deactivating the select transistor MS during programming, erasing, and reading.

The sources 215a, . . . , 215n of the charge retaining transistors M0 are connected to the source line SL. The drains 210a, . . . , 210n of the select transistors MS are connected to the bit line BL. The source line SL and the bit line BL provide the biasing voltage levels to the sources and drains of the charge retaining transistors M0, M1, . . . , Mn for programming, erasing, and reading. In programming the charge retaining transistors M0, the sources 215a, . . . , 215n and drains 220a, . . . , 220n are set to a drain/source programming voltage level that is approximately equal such that the drain-to-source voltage is less than the drain-to-source breakdown voltage level BV_{DS}. By keeping the drain/source programming voltage level applied to the sources 215a, . . . , 215n and drains 220a, . . . , 220n of the selected charge retaining transistors M0, the gate length or the distance of the channel 242 between the sources 215a, . . . , 215n and drains 220a, . . . , 220n of the charge retaining transistors M0 is now determined by the minimum feature size (λ) of the technology in which the flash nonvolatile memory cell 205 is implemented.

A contact region 245 of the first conductivity type D1 connects the substrate SUB to a substrate biasing voltage generator V_{SUB}. A contact region 240 of the first conductivity type D1 connects the single well S-WELL to the single well biasing generator V_{SW}. The substrate biasing voltage generator V_{SUB}, the deep well biasing voltage generator V_{DW}, and the single well biasing generator V_{SW} provide necessary biasing voltages for programming, erasing, and reading the flash nonvolatile memory 205. The diffusion well S-well is formed of a diffusion of the second conductivity type D2 that is implanted into the substrate SUB of the first conductivity type D1. The flash nonvolatile memory cells 205a, . . . , 205n of FIGS. 1c and 1d are SONOS charge trapping layers where the control gate of the select transistor MS is formed with the same structure as the charge retaining transistors M0, M1, . . . , Mn with the first polycrystalline silicon layer eliminated.

When the diffusions of the first conductivity type D1 are implanted with P-type impurities and the diffusions of the second conductivity type are implanted with N-type impurities, the select transistor MS and the charge retaining transistors M0, M1, . . . , Mn are referred to as N-channel transistors. When the diffusions of the first conductivity type D1 are implanted with N-type impurities and the diffusions of the second conductivity type are implanted with P-type impurities, the select transistor MS and the charge retaining transistors M0, M1, . . . , Mn are referred to as P-channel transistors.

In FIGS. 1a and 1c, the triple well construction of the flash nonvolatile memory cells 105 and 205 are structured as NAND floating gate and SONOS charge trapping flash memory cells. However if there is a single charge retaining transistor M0 (n=0), the structure becomes a NOR construction as shown in FIGS. 1b and 1d. The difference being that of the triple well construction of FIGS. 1a and 1c and the single well construction of FIGS. 1b and 1d. The triple well construction of FIGS. 1a and 1c permits a channel Fowler-Nordheim program and erase operation. Conversely, in various embodiments, in the single well construction of FIGS. 1b and 1d, the channel Fowler-Nordheim program and erase operations are not be feasible for the single well implementation with the positive and negative programming and erasing biasing voltages. The junction of the single well S-WELL and the substrates SUB is forward biased to cause an undesired current from or to the S-WELL and the substrates SUB while performing program and erase operations. Therefore, the program and erase operations of the single well construction employs the Fowler-Nordheim drain and source edge tunneling to the charge retaining layer of the memory cells of FIGS. 1b and 1d.

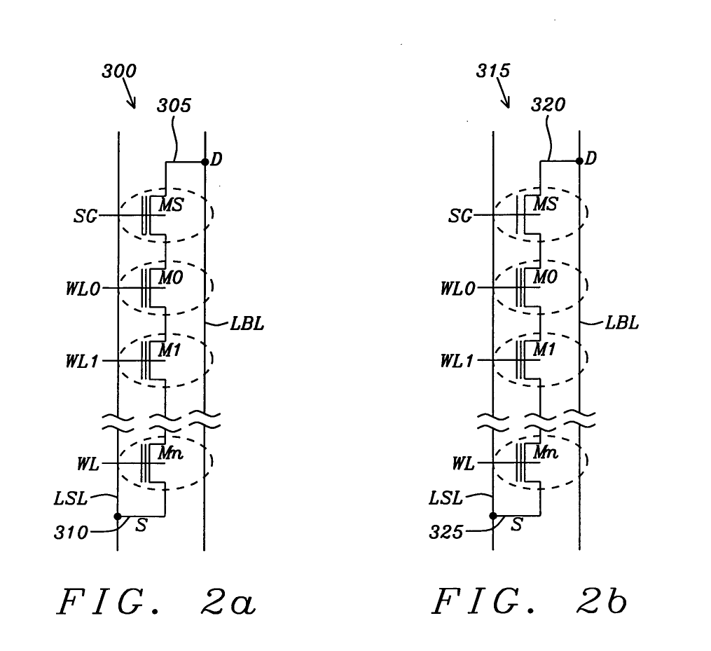

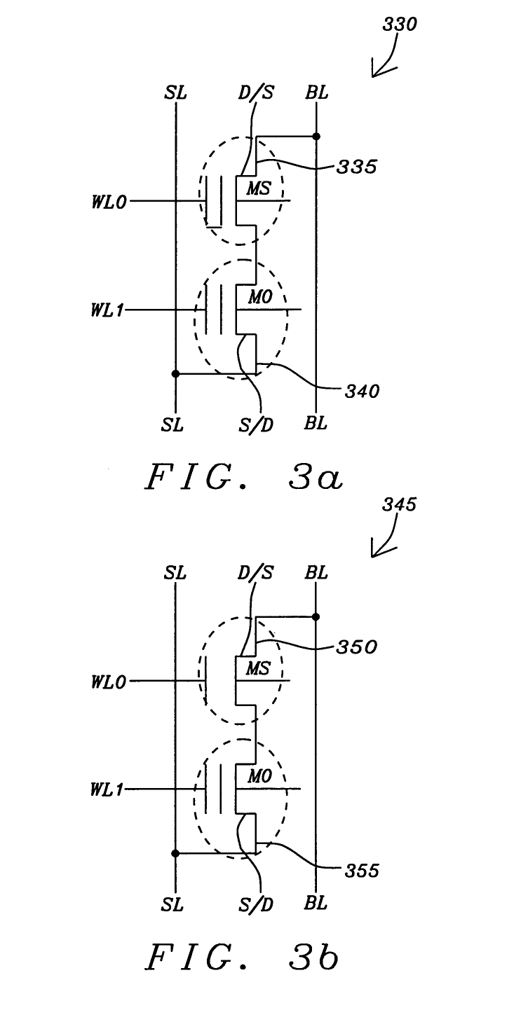

FIG. 2a is a schematic of a floating gate NAND flash nonvolatile memory cell 300. FIG. 2b is a schematic of a SONOS charge trapping NAND flash nonvolatile memory cell 315. In the floating gate NAND flash memory cell, the select transistor MS and two or more charge retaining transistors M0, M1, . . . , Mn are serially connected drain to source. For instance, in some embodiments, there are 32 charge retaining transistors M0, M1, . . . , Mn which provides a 33 transistor Flash nonvolatile memory cell 300. The select transistor MS is formed from a charge retaining transistor structure where the floating gate and the control gate are shorted as described in FIG. 1a.

The drain 305 of the select transistor MS is connected to the bit line BL and the source 310 of the bottommost charge retaining transistor Mn is connected to the source line SL. The bit line BL and the source line SL are placed in parallel and perpendicular to the word line. The bit line BL and the source line SL are associated with a column of NAND flash nonvolatile memory cells 300. The bit line BL and the source line SL transfer the drain/source program voltages during a programming operation to the drains and sources of the selected charge retaining transistor M0, M1, . . . , Mn such that the voltage between the drain and source of the selected charge retaining transistor M0, M1, . . . , Mn does not exceed the drain-to-source breakdown voltage BV_{DS} of the charge retaining transistors M0, M1, . . . , Mn.

The word lines transfer the biasing voltage levels to the control gates of the charge retaining transistors M0, M1, . . . , Mn and the select gate SG controls the activation of the select transistor MS. The select transistor prevents the leakage current in unselected charge retaining transistors M0, M1, . . . , Mn that results from over-erasure during a read operation thus simplifying the programming and erasing of the charge retaining transistors M0, M1, . . . , Mn.

Referring to FIG. 2b, the charge retaining transistors M0, M1, . . . , Mn each have a SONOS structure with a charge trapping silicon nitride layer as described in FIG. 1c. The remaining structure is as described in FIG. 2a. The select transistor MS is a standard MOS transistor structure. As above, the floating gate NAND flash memory cell 315 features the select transistor MS and two or more charge retaining transistors M0, M1, . . . , Mn serially connected drain to source. For instance, in some embodiments, there are 32 charge retaining transistors M0, M1, . . . , Mn which provides a 33 transistor Flash nonvolatile memory cell 315.

The drain 320 of the select transistor MS is connected to the bit line BL and the source 325 of the bottommost charge retaining transistor Mn is connected to the source line SL. The bit line BL and the source line SL are placed in parallel and perpendicular to the word line. The bit line BL and the source line SL are associated with a column of NAND flash nonvolatile memory cells 315. The bit line BL and the source line SL transfer the drain/source program voltages during a programming operation to the drains and sources of the selected charge retaining transistor M0, M1, . . . , Mn such that the voltage between the drain and source of the selected charge retaining transistor M0, M1, . . . , Mn does not exceed the drain-to-source breakdown voltage BV_{DS} of the charge retaining transistors M0, M1, . . . , Mn.

The word lines transfer the biasing voltage levels to the control gates of the charge retaining transistors M0, M1, . . . , Mn and the select gate SG controls the activation of the select transistor MS. The select transistor prevents the leakage current in unselected charge retaining transistors M0, M1, . . . , Mn that results from over-erasure during a read operation thus simplifying the programming and erasing of the charge retaining transistors M0, M1, . . . , Mn.

FIG. 3a is a schematic of a floating gate NOR flash nonvolatile memory cell 330. FIG. 3b is a schematic of a SONOS charge trapping NOR flash nonvolatile memory cell 345. In the floating gate NOR flash memory cell 330, the select transistor MS and one charge retaining transistors M0 are serially connected drain to source. The select transistor MS is formed from a charge retaining transistor structure where the floating gate and the control gate are shorted as described in FIG. 1a.

The drain 335 of the select transistor MS is connected to the bit line BL and the source 340 of the charge retaining transistor M0 is connected to the source line SL. The bit line BL and the source line SL are placed in parallel and perpendicular to the word line. The bit line BL and the source line SL are associated with a column of NOR flash nonvolatile memory cells 330. The bit line BL and the source line SL transfer the drain/source program voltages during a programming operation to the drains and sources of the selected charge retaining transistor M0 such that the voltage between the drain and source of the selected charge retaining transistor M0 does not exceed the drain-to-source breakdown voltage BV_{DS} of the charge retaining transistors M0.

The word line WL transfers the biasing voltage levels to the control gates of the charge retaining transistor M0 and the select gate SG controls the activation of the select transistor MS. The select transistor prevents the leakage current in unselected charge retaining transistor M0 that results from over-erasure during a read operation thus simplifying the programming and erasing of the charge retaining transistors M0.

Referring to FIG. 3b, the charge retaining transistor M0 has a SONOS structure with a charge trapping silicon nitride layer as described in FIGS. 1c and 1d. The remaining structure is as described in FIG. 3a. The select transistor MS is a standard MOS transistor structure. As above, the SONOS charge trapping NOR flash memory cell 345 features the select transistor MS and one charge retaining transistor M0 are serially connected drain to source.

The drain 350 of the select transistor MS is connected to the bit line BL and the source 355 of the charge retaining transistor M0 is connected to the source line SL. The bit line BL and the source line SL are placed in parallel and perpendicular to the word line. The bit line BL and the source line SL are associated with a column of NOR flash nonvolatile memory cells 345. The bit line BL and the source line SL transfer the drain/source program voltages during a programming operation to the drains and sources of the selected charge retaining transistor M0 such that the voltage between the drain and source of the selected charge retaining transistor M0 does not exceed the drain-to-source breakdown voltage BV_{DS} of the charge retaining transistors M0.

The word line WL transfers the biasing voltage levels to the control gates of the charge retaining transistors M0 and the select gate SG controls the activation of the select transistor MS. The select transistor prevents the leakage current in unselected charge retaining transistors M0 that results from over-erasure during a read operation thus simplifying the programming and erasing of the charge retaining transistors M0.

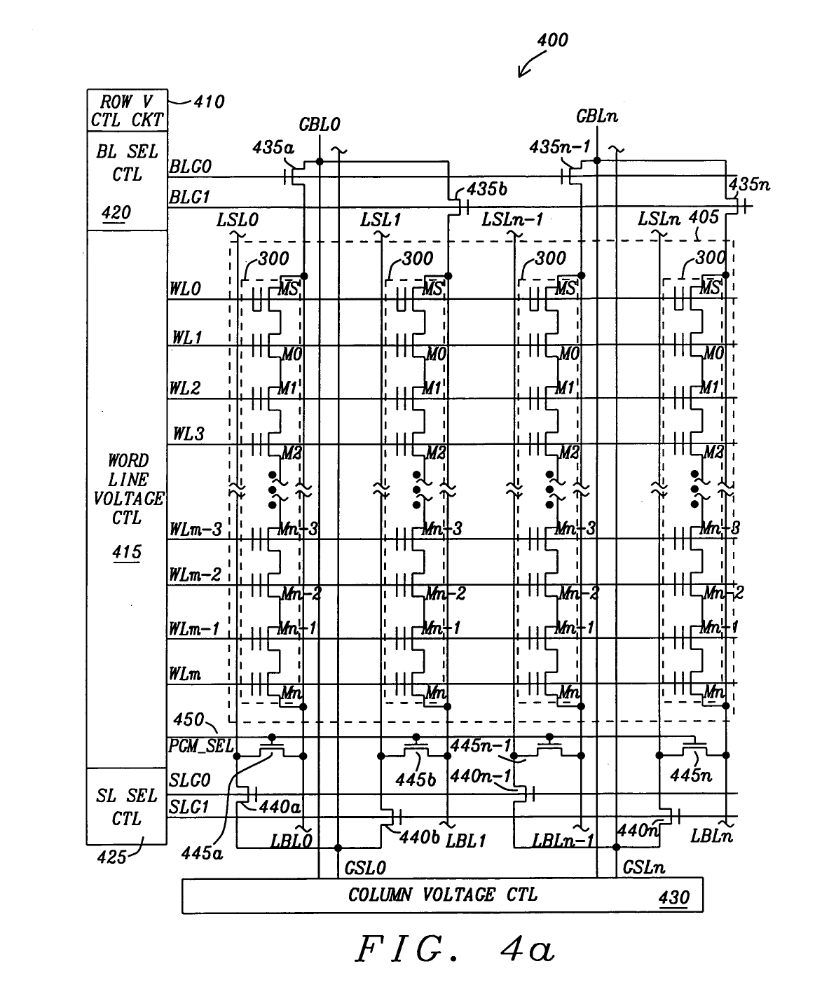

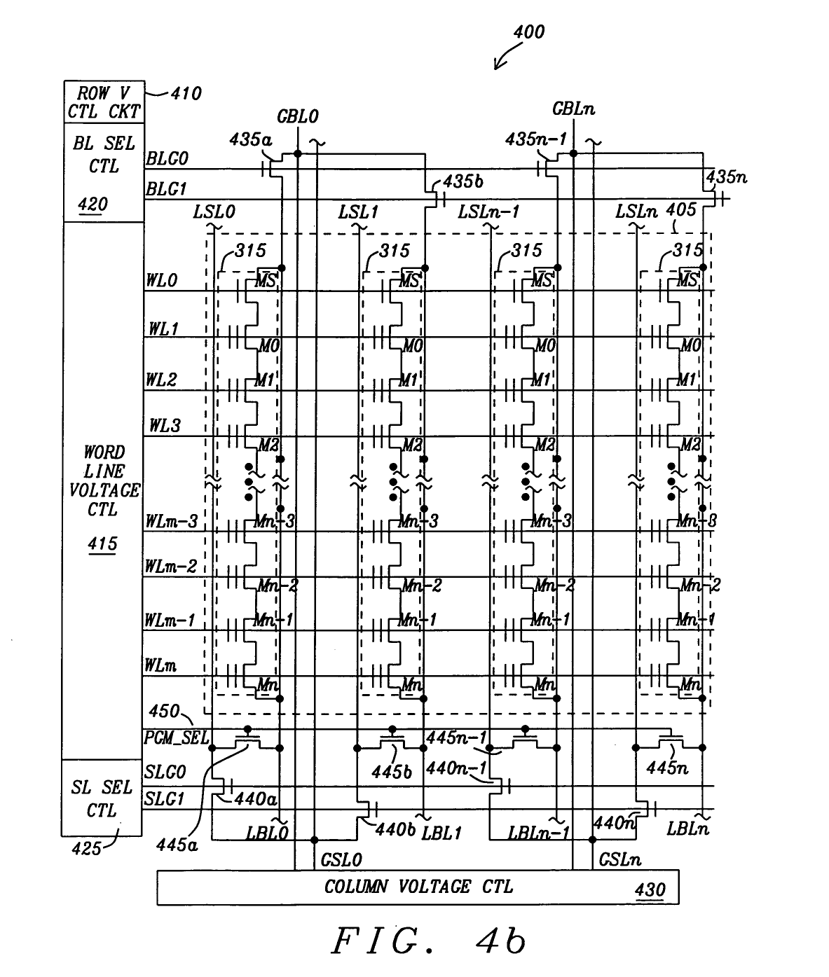

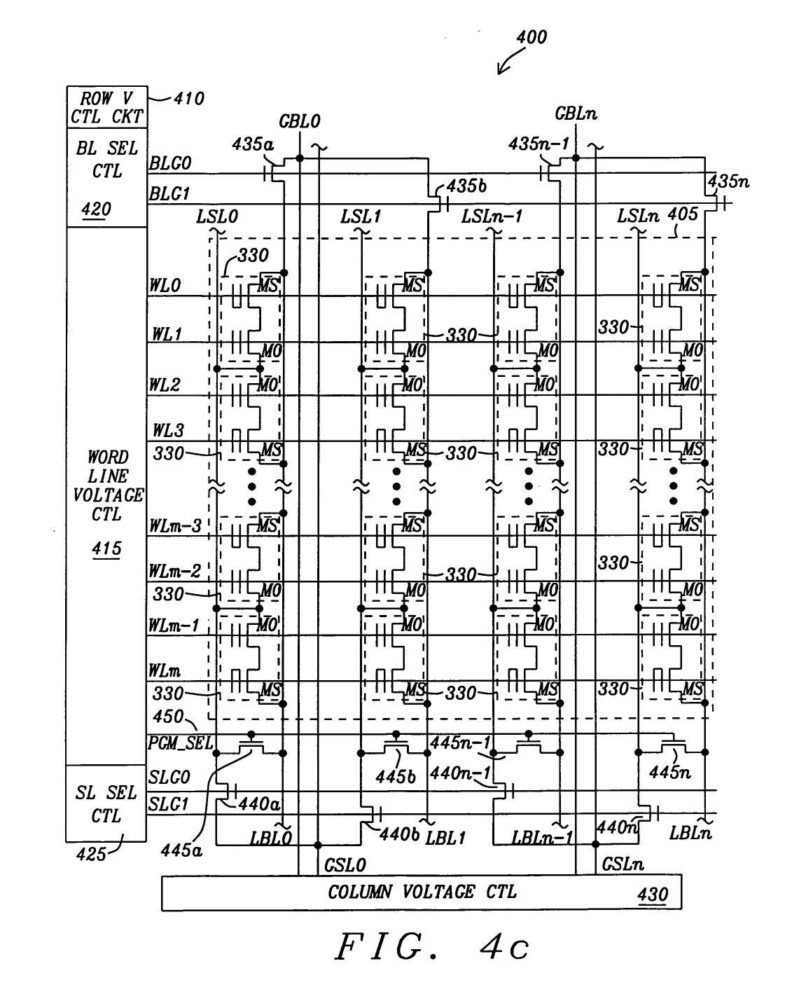

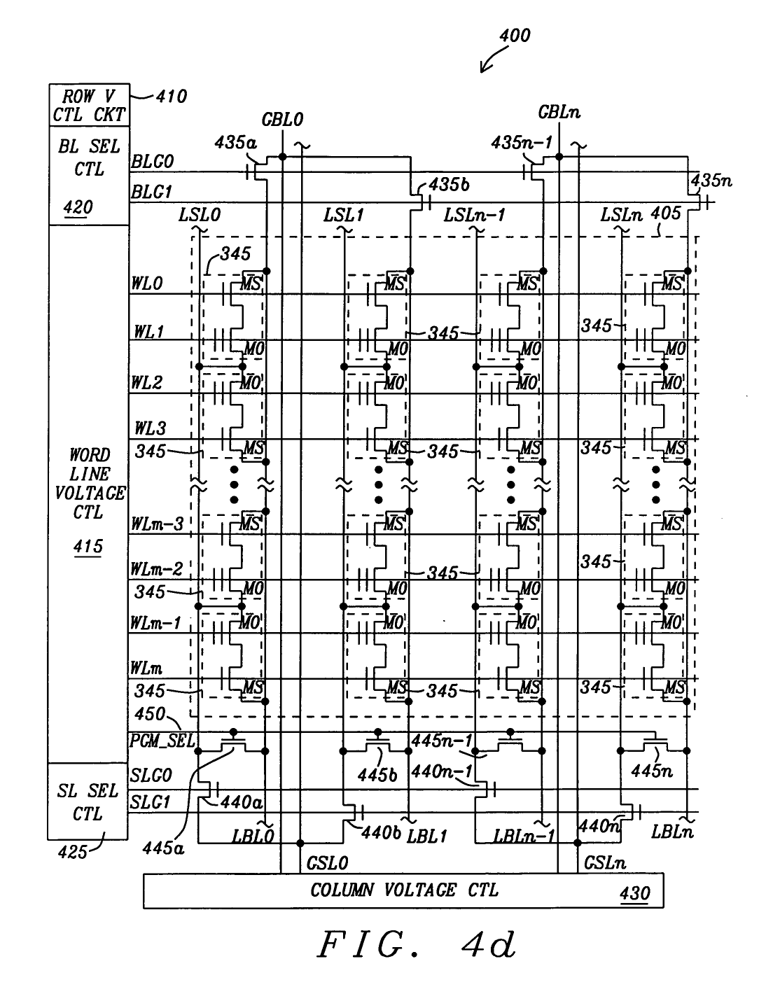

FIG. 4a is a schematic of a flash nonvolatile memory device 400 incorporating an array 405 of floating gate NAND flash nonvolatile memory cells 300. FIG. 4b is a schematic of a flash nonvolatile memory device 400 incorporating an array 405 of SONOS NAND flash nonvolatile memory cells 315. FIG. 4c is a schematic flash nonvolatile memory device 400 incorporating an array 405 of floating gate NOR flash nonvolatile memory cells 330. FIG. 4d is a schematic flash nonvolatile memory device 400 incorporating an array 405 of SONOS NOR flash nonvolatile memory cells 345. Referring to FIG. 4a, the NAND flash nonvolatile memory device 400 includes an array 405 of the floating gate NAND flash nonvolatile memory cells 300 arranged in a matrix of rows and columns. Each of the floating gate NAND flash nonvolatile memory cells 300 includes a select transistor MS and two or more charge retaining transistors M0, M1, . . . , Mn all serially connected. The select transistor MS and the two or more charge retaining transistors M0, M1, . . . , Mn of the floating gate NAND flash nonvolatile memory cells 300 are structured and function as described in FIG. 1a for an N-channel transistor implementation and a P-channel implementation. The drain of the select transistor MS is connected to one of the local metal bit lines LBL0, LBL1, . . . , LBLn−1, and LBLn. The source of the bottommost transistor of the charge retaining transistors Mn is connected of one of the local metal source lines LSL0, LSL1, . . . , LSLn−1, and LSLn. Each of the local bit lines LBL0, LBL1, . . . , LBLn−1, and LBLn and the local source lines LSL0, LSL1, . . . , LSLn−1, and LSLn are arranged in parallel with a column of the array 405 of floating gate NAND flash nonvolatile memory cells 300, The local bit lines LBL0, LBL1, . . . , LBLn−1, and LBLn and the local source lines LSL0, LSL1, . . . , LSLn−1, and LSLn are connected to the floating gate NAND flash nonvolatile memory cells 300 such that in a programming operation, the drain/source program voltage level is applied to the drains and sources of the selected charge retaining transistors M0, M1, . . . , Mn such that the voltage developed between the drain and sources is less than the drain to source breakdown voltage BV_{DS}.

The local metal bit lines LBL0, LBL1, . . . , LBLn−1, and LBLn associated with adjacent columns of the floating gate NAND flash nonvolatile memory cells 300 are connected through the bit line select transistors 435a, . . . , 435n to the global metal bit lines GBL0, . . . , GBLn. The local metal source lines LSL0, LSL1, . . . , LSLn−1, and LSLn associated with adjacent columns of the floating gate NAND flash nonvolatile memory cells 300 are connected through the source line select transistors 440a, . . . , 440n to the global source lines GSL0, . . . , GSLn. The global bit lines GBL0, . . . , GBLn and the global source lines GSL0, . . . , GSLn are connected to the column voltage control circuit 430. The column voltage control circuit 430 generates the appropriate voltage levels for selectively reading, programming, and erasing the floating gate NAND flash nonvolatile memory cells 300.

Each of the control gates of the charge retaining transistors M0, M1, . . . , Mn of the floating gate NAND flash nonvolatile memory cells 300 on each row of the array 405 is connected to one of the word lines WL0, WL1, . . . , WLm−1, and WLm. The word lines WL0, WL1, . . . , WLm−1, and WLm are connected to the word line voltage control sub-circuit 415 in the row voltage control circuit 410.

Each of the gates of the bit line select transistors 435a, . . . , 435n is connected to the bit line select control sub-circuit 420 within the row voltage control circuit 410 to provide the bit line select signals BLG0 and BLG1 for activation of the bit line select transistors 435a, . . . , 435n to connect a selected local bit lines LBL0, LBL1, . . . , LBLn−1, and LBLn to its associated global bit line GBL0, . . . , GBLn. Each of the gates of the source line select transistors 440a, . . . , 440n is connected to the source line select control sub-circuit 425 within the row voltage control circuit 410 to provide the source line select signals SLG0 and SLG1 for activation of the source line select transistors 440a, . . . , 440n to connect a selected local source lines LSL0, LSL1, . . . , LSLn−1, and LSLn to its associated global source line GSL0, . . . , GSLn.

The array 405 of floating gate NAND flash nonvolatile memory cells 300 includes at least one block (as shown) of the floating gate NAND flash nonvolatile memory cells 300 and may have multiple blocks.

Each of the local bit lines LBL0, LBL1, . . . , LBLn−1, and LBLn are connected to their associated local source lines LSL0, LSL1, . . . , LSLn−1, and LSLn through the pass transistors 445a, 445b, . . . , 445n. The gates of the pass transistors 445a, 445b, . . . , 445n are connected to the program select signal 450 to bring the local bit line LBL0, LBL1, . . . , LBLn−1, and LBLn and the local source lines LSL0, LSL1, . . . , LSLn−1, and LSLn to the equal potential voltage level of the drain/source voltage level during a program operation to prevent punch through between the drains and sources of the charge retaining transistors M0, M1, . . . , Mn.

Referring to FIG. 4b, the flash nonvolatile memory device 400 includes an array 405 of the SONOS NAND flash nonvolatile memory cells 315 arranged in a matrix of rows and columns. Each of the SONOS NAND flash nonvolatile memory cells 315 includes a select transistor MS and two or more charge retaining transistors M0, M1, . . . , Mn all serially connected. The select transistor MS and the two or more charge retaining transistors M0, M1, . . . , Mn of the floating gate NAND flash nonvolatile memory cells 300 are structured and function as described in FIG. 2a for an N-channel transistor implementation and a P-channel implementation. The remaining structure and function is as described in FIG. 4a.

Referring to FIG. 4c, the flash nonvolatile memory device 400 includes an array 405 of the floating gate NOR flash nonvolatile memory cells 330 arranged in a matrix of rows and columns. Each of the floating gate NOR flash nonvolatile memory cells 330 includes a select transistor MS and one charge retaining transistor M0 connected serially. The select transistor MS and the charge retaining transistor of the floating gate NOR flash nonvolatile memory cells 330 are structured and function as described in FIG. 2c for an N-channel transistor implementation and for a P-channel implementation. The remaining structure and function is as described in FIG. 4a.

Referring to FIG. 4d, the flash nonvolatile memory device 400 includes an array 405 of the SONOS NOR flash nonvolatile memory cells 345 arranged in a matrix of rows and columns. Each of the SONOS NOR flash nonvolatile memory cells 345 includes a select transistor MS and one charge retaining transistor M0 connected serially. The select transistor MS and the charge retaining transistor of the SONOS NOR flash nonvolatile memory cells 345 are structured and function as described in FIG. 2d for an N-channel transistor implementation and a P-channel implementation. The remaining structure and function is as described in FIG. 4a.

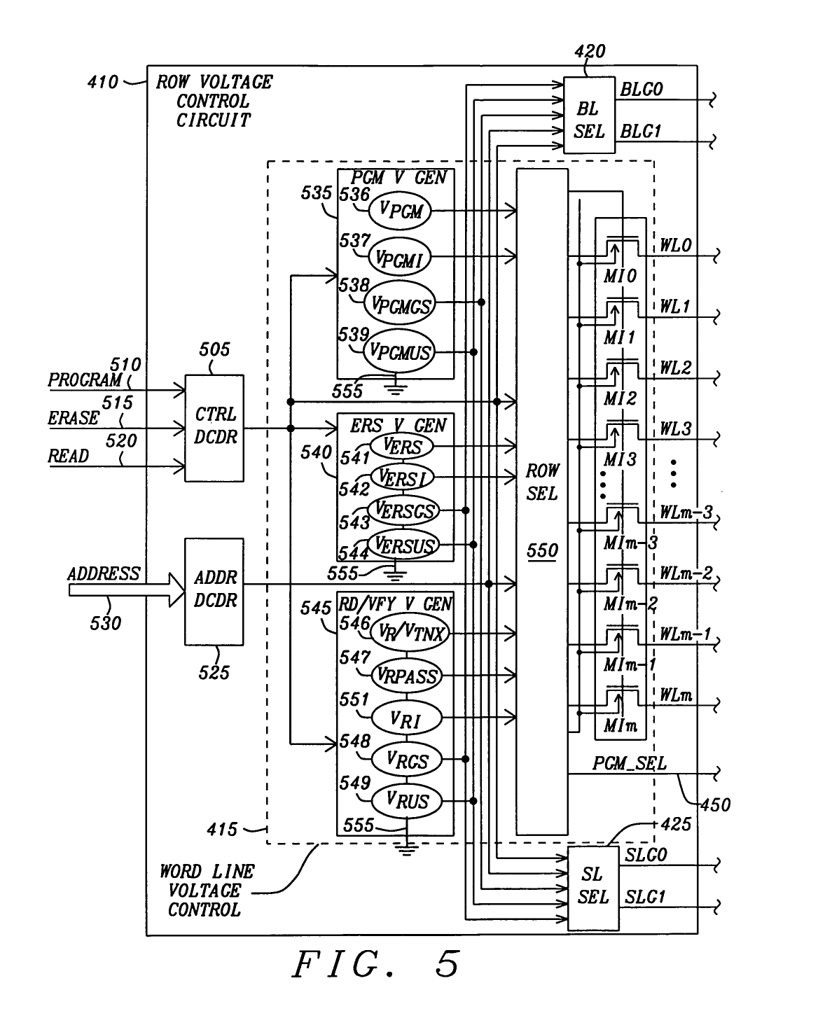

Refer now to FIG. 5 for a description of the row voltage control circuit 410. The row voltage control circuit 410 has a control decoder 505 that receives program timing and control signals 510, erase timing and control signals 515, and read timing and control signals 520. The control decoder 505 decodes the program timing and control signals 510, erase timing and control signals 515, and read timing and control signals 520 to establish the operation of the flash nonvolatile memory device 400. The row voltage control circuit 410 has an address decoder 525 that receives and decodes an address signal 530 that provides the location of the selected charge retaining flash cells 300, 315, 330, or 345 that are to be programmed, erased, or read.

The bit line select control sub-circuit 420 receives the decoded program, erase, and read timing and control signals from the control decoder 505 and the decoded addresses from the address decoder 525. The bit line select control sub-circuit 420 selects which of the bit line select signals BLG0 and BLG1 that activates the bit line select transistors 435a, . . . , 435n that connects the local bit line LBL0, LBL1, . . . , LBLn−1, and LBLn to which the selected flash nonvolatile memory devices 400 are connected to the associated global bit lines GBL0, . . . , GBLn.

The source line select control sub-circuit 425 receives the decoded program, erase, and read timing and control signals from the control decoder 505 and the decoded addresses from the address decoder 525. The source line select control sub-circuit 425 selects which of the source line select signals SLG0 and SLG1 that activates the source line select transistors 440a, . . . , 440n that connects the local source lines LSL0, LSL1, . . . , LSLn−1, and LSLn to which the selected flash nonvolatile memory device 400 is connected to the associated global source lines GSL0, . . . , GSLn.

The row voltage control circuit 410 includes the word line voltage control circuit 415 that has a program voltage generator 535, an erase voltage generator 540, a read voltage generator 545, and a row selector 550. The row selector 550 for transferring the program, erase, and read voltages from the program voltage generator 535, the erase voltage generator 540, and the read voltage generator 545 through the pass gate transistors MI0, MI1, . . . , MIm−1, MIm to the selected word lines WL0, WL1, . . . , WLm−1, and WLm. Further, during a program operation, the row selector 550 activates the program select line 550 to turn on the pass transistors 445a, 445b, . . . , 445n to bring the local bit line LBL0, LBL1, . . . , LBLn−1, and LBLn and the local source lines LSL0, LSL1, . . . , LSLn−1, and LSLn to an equal potential voltage level during a program operation to prevent punch through between the drains and sources of the charge retaining transistors M0, . . . and Mn.

The program voltage generator 535 has a program voltage source 536 that is connected to the row selector 550 to provide a program voltage level V_{PGM}. The program voltage level V_{PGM} is applied to one of the selected word lines WL0, WL1, . . . , WLm−1, and WLm for setting the voltage threshold of the selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. A program inhibit voltage generator 537 provides a program inhibit voltage level V_{PGMI} to is transferred to the row selector 550 to be applied to the unselected word lines WL0, WL1, . . . , WLm−1, and WLm for inhibiting a disturb programming of the unselected pages of the array 405 of floating gate NAND flash nonvolatile memory cells 300, SONOS NAND flash nonvolatile memory cells 315, floating gate NOR flash nonvolatile memory cells 330, or SONOS NOR flash nonvolatile memory cells 345.

The program select gating voltage generator 538 generates the program select gating voltage V_{PMGS} that is transferred to the bit line select control sub-circuit 420 and source line select control sub-circuit 425 for connecting global bit lines GBL0, . . . , GBLn to the local bit line LBL0, LBL1, . . . , LBLn−1, and LBLn and the global source lines GSL0, . . . , GSLn and the local source lines LSL0, LSL1, . . . , LSLn−1, and LSLn for providing the programming voltage level to drains and the sources of the selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. The program unselect gating voltage generator 539 generates the program unselect gating voltage V_{PMGU} that is transferred to the bit line select control sub-circuit 420 and source line select control sub-circuit 425 for disconnecting global bit lines GBL0, . . . , GBLn to the local bit line LBL0, LBL1, . . . , LBLn−1, and LBLn and the global source lines GSL0, . . . , GSLn and the local source lines LSL0, LSL1, . . . , LSLn−1, and LSLn for blocking the programming voltage level to drains and the sources of the unselected floating gate NAND flash nonvolatile memory cells 300, SONOS NAND flash nonvolatile memory cells 315, floating gate NOR flash nonvolatile memory cells 330, or SONOS NOR flash nonvolatile memory cells 345.

The erase voltage generator 540 has a erase voltage generator 541 that is connected to the row selector 550 to provide the erase voltage level V_{ERS} to the word lines WL0, WL1, . . . , WLm−1, and WLm of the selected pages of the flash nonvolatile memory device 400 to erase selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. The erase voltage generator 540 also has a erase inhibit voltage generator 542 that is connected to the row selector 450 to provide the necessary erase inhibit voltage level V_{ERSI} to the word lines WL0, WL1, . . . , WLm−1, and WLm of the unselected pages of the flash nonvolatile memory device 400 to prevent erasing of the unselected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. The erase voltage generator 540 includes an erase select gating voltage generator 543 to provide the erase select gate voltage level V_{ERSGS} to the bit line select control sub-circuit 420 and source line select control sub-circuit 425 for providing the erase select gate voltage level V_{ERSGS} to connect global bit lines GBL0, . . . , GBLn to the local bit line LBL0, LBL1, . . . , LBLn−1, and LBLn and the global source lines GSL0, . . . , GSLn and the local source lines LSL0, LSL1, . . . , LSLn−1, and LSLn. The erase voltage generator 540 includes an erase unselect gating voltage generator 544 to provide the erase unselect gate voltage level V_{ERSGU} to the bit line select control sub-circuit 420 and source line select control sub-circuit 425 for providing the erase unselect gate voltage level V_{ERSGU} to disconnect global bit lines GBL0, . . . , GBLn from the local bit line LBL0, LBL1, . . . , LBLn−1, and LBLn and the global source lines GSL0, . . . , GSLn and the local source lines LSL0, LSL1, . . . , LSLn−1, and LSLn.

The read voltage generator 545 has a read/verify voltage generator 546 to provide the necessary read reference voltage V_{R} and a verify threshold voltage levels Vtnx to the control gates of the selected word line of the floating gate NAND flash nonvolatile memory cells 300, SONOS NAND flash nonvolatile memory cells 315, floating gate NOR flash nonvolatile memory cells 330, or SONOS NOR flash nonvolatile memory cells 345 for reading cell data. The read voltage generator 545 has read pass voltage generator 547 to provide the read pass voltage level V_{RPASS} to the control gate of the unselected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. The read voltage generator 545 has read inhibit voltage generator 551 to provide the read inhibit voltage level V_{RI} to the control gate of the floating gate NAND flash nonvolatile memory cells 300, SONOS NAND flash nonvolatile memory cells 315, floating gate NOR flash nonvolatile memory cells 330, or SONOS NOR flash nonvolatile memory cells 345.

The read voltage generator 545 has a read select voltage generator 548 to provide a read select gate voltage level V_{RGS} to the gates of the bit line select transistors 435a, . . . , 435n and source line select transistors 440a, . . . , 440n for connecting the global bit lines GBL0, . . . , GBLn to the local bit line LBL0, LBL1, . . . , LBLn−1, and LBLn and the global source lines GSL0, . . . , GSLn to the local source lines LSL0, LSL1, . . . , LSLn−1, and LSLn in a read or verify operation. The read voltage generator 545 has a read unselect voltage generator 548 to provide a read unselect gate voltage level V_{RGU} to the gates of the bit line select transistors 435a, . . . , 435n and source line select transistors 440a, . . . , 440n for disconnecting the global bit lines GBL0, . . . , GBLn from the local bit line LBL0, LBL1, . . . , LBLn−1, and LBLn and the global source lines GSL0, . . . , GSLn from the local source lines LSL0, LSL1, . . . , LSLn−1, and LSLn in a read or verify operation.

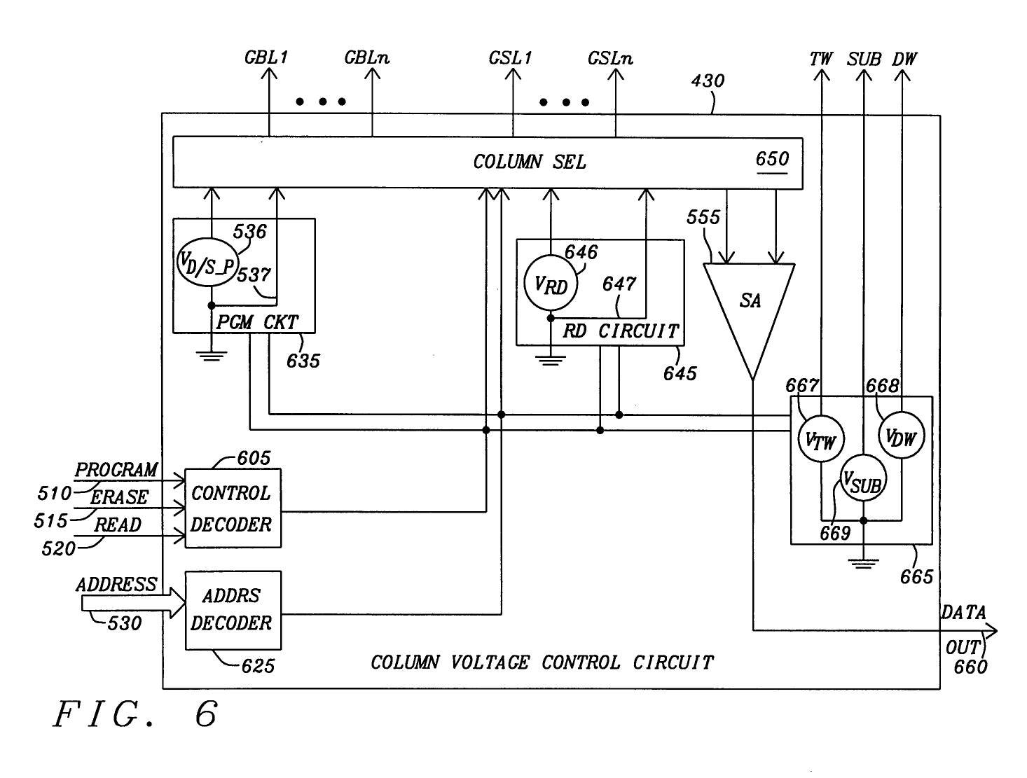

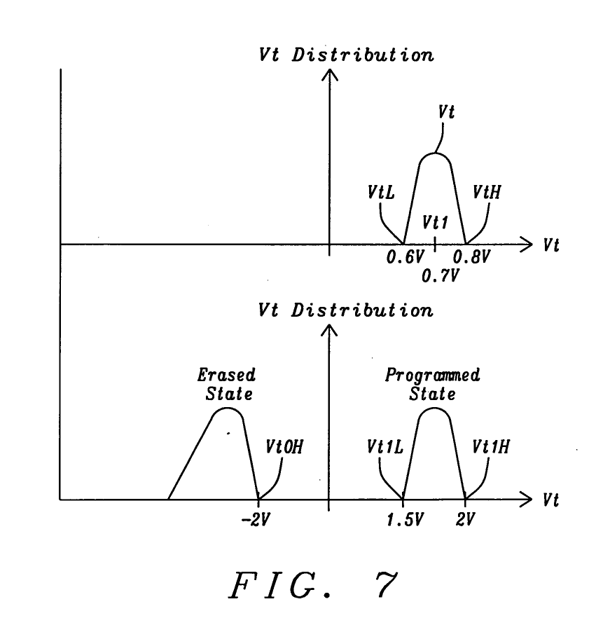

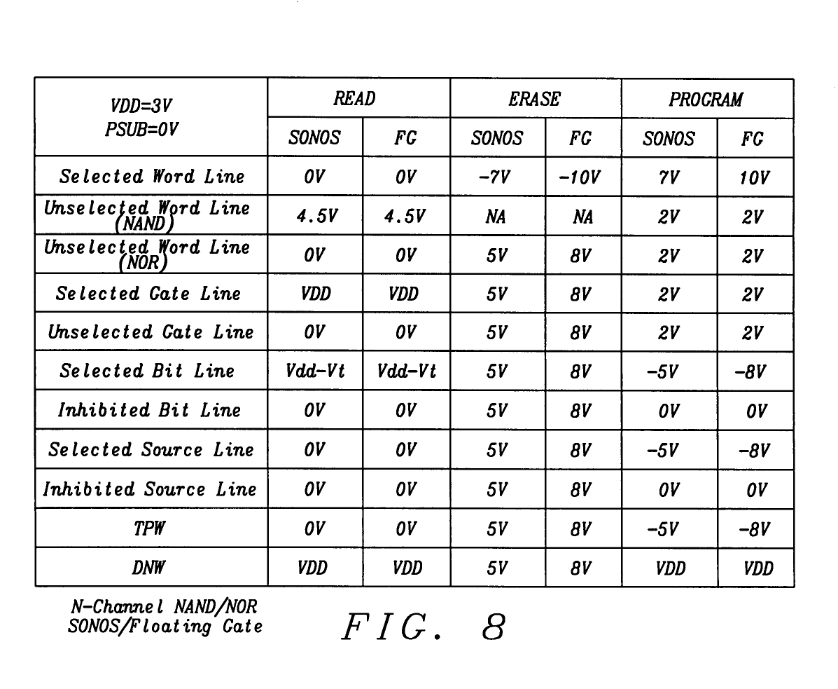

Refer now to FIG. 6 for a description of the column voltage control circuit 355. The column voltage control circuit 430 has a control decoder 505 that receives program timing and control signals 510, erase timing and control signals 515, and read timing and control signals 520. The control decoder 505 decodes the program timing and control signals 510, erase timing and control signals 515, and read timing and control signals 520 to establish the operation of the flash nonvolatile memory device 400. The column voltage control circuit 355 has an address decoder 525 that receives and decodes an address signal 530 that provides the locations of the selected charge retaining cell 310 that are to be programmed, erased, or read.

The column voltage control circuit 430 includes a program voltage generator 635, a read voltage generator 645, and a column selector 650. The program voltage generator 635 has a program voltage source 636 that provides a drain/source program voltage level V_{D/S}_{_{—}}_{P} to the drains and sources floating gate NAND flash nonvolatile memory cells 300, SONOS NAND flash nonvolatile memory cells 315, floating gate NOR flash nonvolatile memory cells 330, or SONOS NOR flash nonvolatile memory cells 345 for programming of the selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. A ground reference voltage level 637 is provided to drain and source of the selected charge retaining transistors M0, . . . −Mn during the program operation to establish the voltage field between the charge retaining layer and the sources and drains of the floating gate NAND flash nonvolatile memory cells 300, SONOS NAND flash nonvolatile memory cells 315, floating gate NOR flash nonvolatile memory cells 330, or SONOS NOR flash nonvolatile memory cells 345 for inhibiting programming the selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345.

During the erase operation of this invention, the sources and drains of the floating gate NAND flash nonvolatile memory cells 300, SONOS NAND flash nonvolatile memory cells 315, floating gate NOR flash nonvolatile memory cells 330, or SONOS NOR flash nonvolatile memory cells 345 are coupled to a drain/source erase voltage level V_{TW} from the diffusion well (TPW, N-WELL, TNW). The global bit lines GBL0, . . . , GBLn and the global source lines GSL0, . . . , GSLn are disconnected within the column selector 650 and allowed to float.

The read voltage generator 645 has a read bias voltage source 646 to provide the necessary read bias voltage V_{RDB} to the global bit lines GBL0, . . . , GBLn and thus to the drain/source of the selected of the floating gate NAND flash nonvolatile memory cells 300, SONOS NAND flash nonvolatile memory cells 315, floating gate NOR flash nonvolatile memory cells 330, or SONOS NOR flash nonvolatile memory cells 345 for reading the data state of the selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. The read voltage generator also provides the ground reference voltage level 647 to the global source lines GSL0, . . . , GSLn and thus to the floating gate NAND flash nonvolatile memory cells 300, SONOS NAND flash nonvolatile memory cells 315, floating gate NOR flash nonvolatile memory cells 330, or SONOS NOR flash nonvolatile memory cells 345. In the read operation, the global bit lines GBL0, . . . , GBLn are connected to the sense amplifier 655 by the column selector 650 to determine the data state of the selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. The data state is transferred to the external circuitry through the data output terminal 660.

The column selector 650 provides the select switching signals for transferring the program, erase (floating), and read voltages from the program voltage generator 635 and the read voltage generator 645 to the selected global bit lines GBL0, GBLn and selected global source lines GSL0, . . . , GSLn.

The column voltage control circuit 430 has a well bias control circuit 665 that includes a diffusion well voltage generator 667, a deep well voltage generator 668 and a substrate biasing voltage generator 669. The diffusion well voltage generator 667 is connected to the triple diffusion well of FIG. 1a or 2a or the shallow diffusion well S-WELL of FIG. 1b or 2b. The deep well generator 668 is connected to a deep diffusion well of FIG. 1a or 2a. The substrate biasing voltage generator 669 is connected to the substrate SUB to provide a substrate biasing voltage level V_{SUB}. The substrate biasing voltage level V_{SUB} is the ground reference voltage level or the voltage level of the power supply voltage source to the substrate SUB dependent upon the impurity type of the substrate SUB. In embodiments where the substrate SUB is an N-type impurity, the substrate biasing voltage level V_{SUB} is the ground reference voltage level. In embodiments where the substrate SUB is a P-type impurity, the substrate biasing voltage level V_{SUB} is the voltage level of the power supply voltage source VDD.

The deep well voltage generator 668 generates a deep well biasing voltage level V_{DW} for those embodiments including a triple well structure as in FIG. 1a or 2a. For programming, verification, and reading of the array 405 of floating gate NAND flash nonvolatile memory cells 300, SONOS NAND flash nonvolatile memory cells 315, floating gate NOR flash nonvolatile memory cells 330, or SONOS NOR flash nonvolatile memory cells 345, the deep well biasing voltage level V_{DW} is the voltage level of the power supply voltage source for the embodiments where the deep well D-WELL is doped with an N-type impurity. Also, for programming, verification, and reading of the array 405 of floating gate NAND flash nonvolatile memory cells 300, SONOS NAND flash nonvolatile memory cells 315, floating gate NOR flash nonvolatile memory cells 330, or SONOS NOR flash nonvolatile memory cells 345, the deep well biasing voltage level V_{DW} is the ground reference voltage level for the embodiments where the deep well D-WELL is doped with an P-type impurity. For erasing a selected array 405 of the array 400 of floating gate NAND flash nonvolatile memory cells 300, SONOS NAND flash nonvolatile memory cells 315, floating gate NOR flash nonvolatile memory cells 330, or SONOS NOR flash nonvolatile memory cells 345, the deep well biasing voltage level V_{DW} is a well erase biasing voltage level.

The shallow well voltage generator 667 transfers a diffusion well voltage level V_{TW} to the triple wells T-WELL FIG. 1a or 2a or the diffusion well S-WELL of FIG. 1b or 2b. The shallow well voltage generator 667 generates the erase voltage level that is applied to the triple wells T-WELL and the diffusion well S-WELL to attract the charges from or to the charge retaining layer of the selected floating gate NAND flash nonvolatile memory cells 300, SONOS NAND flash nonvolatile memory cells 315, floating gate NOR flash nonvolatile memory cells 330, or SONOS NOR flash nonvolatile memory cells 345. The erase voltage level that is generated by the deep well generator 668 and the shallow well generator 667 prevent undesired forward currents between the deep wells D-WELL and the triple wells T-WELL. Similarly, the shallow well voltage generator 667 generates the program voltage level that is applied to the triple wells T-WELL and the diffusion well S-WELL to attract the charges from or to the charge retaining of the floating gate NAND flash nonvolatile memory cells 300, SONOS NAND flash nonvolatile memory cells 315, floating gate NOR flash nonvolatile memory cells 330, or SONOS NOR flash nonvolatile memory cells 345

FIG. 7 is a graph of threshold voltage levels for various embodiments of an N-channel transistor floating gate and SONOS charge trapping NAND and NOR flash memory cells. The erased state for the N-channel charge retaining transistors M0, M1, . . . , Mn has a threshold voltage level distribution that has a lower limit Vt1L of 1.5V and an upper limit Vt1H of 2V. The programmed state for the N-channel charge retaining transistors M0, M1, . . . , Mn has a threshold voltage level distribution that has a lower limit Vt0H of −2V. During a read operation, the read reference voltage level V_{R} for the charge retaining transistors M0, M1, . . . , Mn is approximately 0V. The threshold voltage of the select transistor MS has a nominal voltage level of approximately 0.7V with a lower limit VtL of approximately 0.6V and a upper limit VtH of approximately 0.8V

FIG. 8 is a table illustrating the voltage conditions for operating an array of an array of N-channel floating gate and SONOS charge trapping transistor NAND or NOR flash memory cells for reading, erasing, and programming, selected of N-channel floating gate and SONOS charge trapping transistors. For erasing selected N-channel floating gate transistors of NAND and NOR flash memory cells, a negative erase voltage level of approximately −10V+/−2V applied to the control gate and a positive erase voltage level of approximately 8V+/−2V is applied to the triple P-well and the deep N-well and coupled to the drains and sources for the N-channel charge retaining transistors M0, M1, . . . , Mn. For the selected N-channel SONOS charge trapping transistors of NAND and NOR memory cells, the negative erase voltage level of approximately −7V+/−1V is applied to the control gate and a positive erase voltage level of approximately 5V+/−1V is applied to the triple P-well and the deep N-well and coupled to the drains and sources for the N-channel charge retaining transistors M0, M1, . . . , Mn. The voltage levels of the positive and negative erase voltage level are split such that the voltage field between the charge retaining (floating gate, SONOS charge trapping) layer and the triple P-well is sufficiently large to trigger the Fowler-Nordheim tunneling. The voltage levels of the positive and negative erase voltage level have magnitudes that are equal to or less than the drain to source breakdown voltage BV_{DS} of the peripheral circuitry generating and distributing the positive and negative erase biasing voltages.

For programming selected N-channel floating gate transistors of NAND and NOR flash memory cells, a positive program voltage level of approximately 10V+/−2V applied to the control gate and a negative program voltage level of approximately −8V+/−2V is applied to the bit lines LBL and the source lines LSL and thus to the drains and sources of the selected N-channel floating gate transistors M0, M1, . . . , Mn of the NAND and NOR flash memory cells. The negative program voltage level is applied to the triple P-well and the voltage level of the power supply voltage source (VDD) is applied to the deep N-well.

For programming selected N-channel SONOS charge trapping transistors of the NAND and NOR flash memory cells, a positive program voltage level of approximately 7V+/−1V applied to the control gate and a negative program voltage level of approximately −5V+/−1V is applied to the bit lines LBL and the source lines LSL and thus to the drains and sources of the selected N-channel floating gate transistors M0, M1, . . . , Mn of the NAND and NOR flash memory cells. The negative program voltage level is applied to the triple P-well and the voltage level of the power supply voltage source (VDD) is applied to the deep N-well. The voltage levels of the positive and negative program voltage level are split such that the voltage field between the charge retaining (floating gate, SONOS charge trapping) layer and the triple P-well is sufficiently large to trigger the Fowler-Nordheim tunneling. The voltage levels of the positive and negative program voltage level have magnitudes that are equal to or less than the drain to source breakdown voltage BV_{DS} of the peripheral circuitry generating and distributing the positive and negative program biasing voltages.

The negative program voltage level is applied equally to the bit lines LBL and the source lines LSL and thus to the drains and sources of the selected N-channel floating gate transistors M0, M1, . . . , Mn of the NAND and NOR flash memory cells to insure that the voltage difference between the drains and sources is less than the drain-to-source breakdown voltage BV_{DS}. Insuring that the voltage difference between the drains and sources is less than the drain-to-source breakdown voltage BV_{DS} allows the gate length of the N-channel charge retaining transistors M0, M1, . . . , Mn to be limited only by the minimum feature size (λ) of the technology being employed to implement the N-channel SONOS charge trapping transistors of the NAND and NOR flash memory cells.

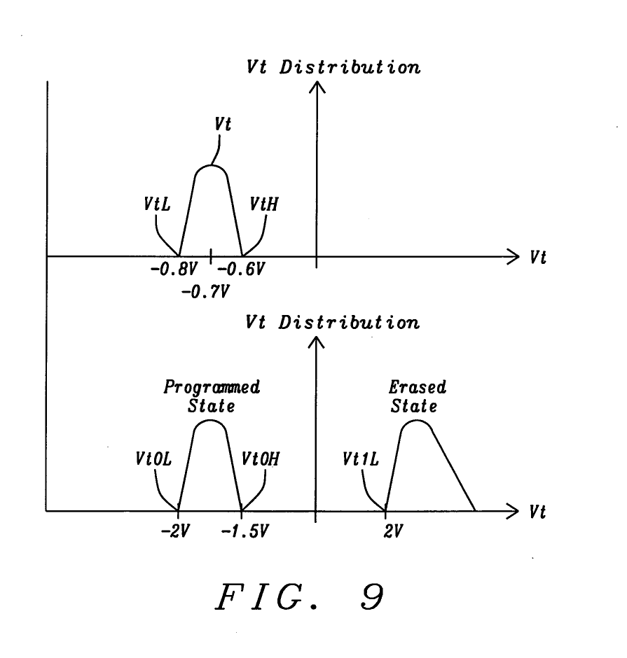

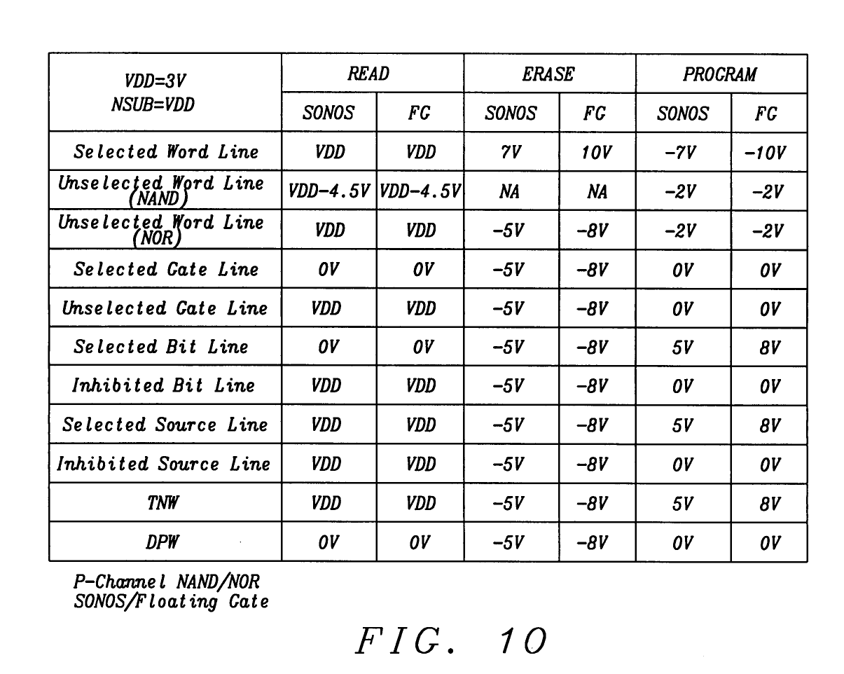

FIG. 9 is a graph of threshold voltage levels for various embodiments of a P-channel transistor floating gate and SONOS charge trapping NAND and NOR flash memory cells. The erased state for the P-channel charge retaining transistors M0, M1, . . . , Mn has a threshold voltage level distribution that has a lower limit Vt1L of approximately 2V. The programmed state for the P-channel charge retaining transistors M0, M1, . . . , Mn has a threshold voltage level distribution that has an upper limit Vt0H of −1.5V and a lower limit Vt0L of −2V. During a read operation, the read reference voltage level V_{R} for the P-channel charge retaining transistors M0, M1, . . . , Mn is approximately 0V. The threshold voltage of the select transistor MS has a nominal voltage level of approximately −0.7V with a lower limit VtL of approximately −0.8V and a upper limit VtH of approximately −0.6V

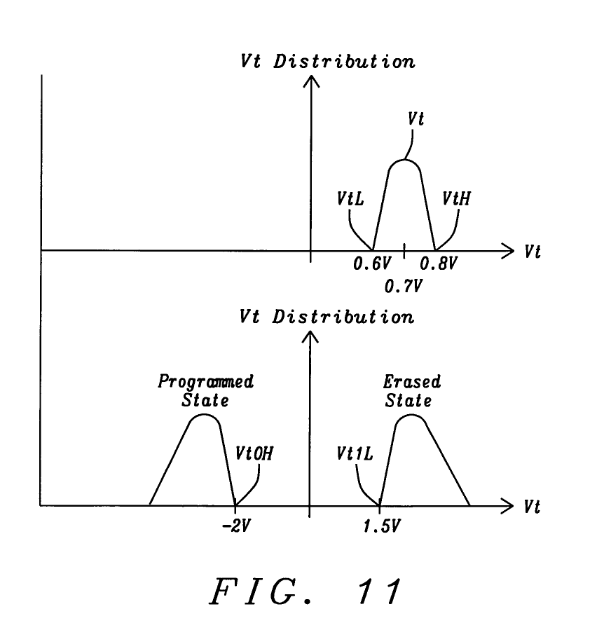

FIG. 10 is a table illustrating the voltage conditions for operating an array of an array of P-channel floating gate and SONOS charge trapping transistor NAND or NOR flash memory cells for reading, erasing, and programming, selected of P-channel floating gate and SONOS charge trapping transistors. For erasing selected P-channel floating gate transistors of NAND and NOR flash memory cells, a positive erase voltage level of approximately 10V+/−2V applied to the control gate and a negative erase voltage level of approximately −8V+/−2V is applied to the triple N-well and the deep P-well and coupled to the drains and sources for the charge retaining transistors M0, M1, . . . , Mn. For the selected P-channel SONOS charge trapping transistors of NAND and NOR memory cells, a positive erase voltage level of approximately 7V+/−1V is applied to the control gate and a negative erase voltage level of approximately −5V+/−1V is applied to the triple N-well and the deep P-well and coupled to the drains and sources for the charge retaining transistors M0, M1, . . . , Mn. The voltage levels of the positive and negative erase voltage level are split such that the voltage field between the charge retaining (floating gate, SONOS charge trapping) layer and the triple P-well is sufficiently large to trigger the Fowler-Nordheim tunneling. The voltage levels of the positive and negative erase voltage level have magnitudes that are equal to or less than the drain to source breakdown voltage BV_{DS} of the peripheral circuitry generating and distributing the positive and negative erase biasing voltages.

For programming selected P-channel floating gate transistors of NAND and NOR flash memory cells, a negative program voltage level of approximately −10V+/−2V applied to the control gate and a positive program voltage level of approximately 8V+/−2V is applied to the bit lines LBL and the source lines LSL and thus to the drains and sources of the selected P-channel floating gate transistors M0, M1, . . . , Mn of the NAND and NOR flash memory cells. The positive program voltage level of approximately 8V+/−2V is applied to the triple N-well and the voltage level of the ground reference voltage level (0V) is applied to the deep P-well.

For programming selected P-channel SONOS charge trapping transistors of the NAND and NOR flash memory cells, a negative program voltage level of approximately −7V+/−1V applied to the control gate and a positive program voltage level of approximately 5V+/−1V is applied to the bit lines LBL and the source lines LSL and thus to the drains and sources of the selected P-channel floating gate transistors M0, M1, . . . , Mn of the NAND and NOR flash memory cells. The positive program voltage level of approximately 5V+/−1V is applied to the triple N-well and the voltage level of the ground reference voltage level (0V) is applied to the deep P-well. The voltage levels of the positive and negative program voltage level are split such that the voltage field between the charge retaining (floating gate, SONOS charge trapping) layer and the triple N-well is sufficiently large to trigger the Fowler-Nordheim tunneling. The voltage levels of the positive and negative program voltage level have magnitudes that are equal to or less than the drain to source breakdown voltage BV_{DS} of the peripheral circuitry generating and distributing the positive and negative program biasing voltages.

The positive program voltage level is applied equally to the bit lines LBL and the source lines LSL and thus to the drains and sources of the selected P-channel floating gate transistors M0, M1, . . . , Mn of the NAND and NOR flash memory cells to insure that the voltage difference between the drains and sources is less than the drain-to-source breakdown voltage BV_{DS}. Insuring that the voltage difference between the drains and sources is less than the drain-to-source breakdown voltage BV_{DS} allows the gate length of the charge retaining transistors M0, M1, . . . , Mn to be limited only by the minimum feature size (λ) of the technology being employed to implement the P-channel SONOS charge trapping transistors of the NAND and NOR flash memory cells.

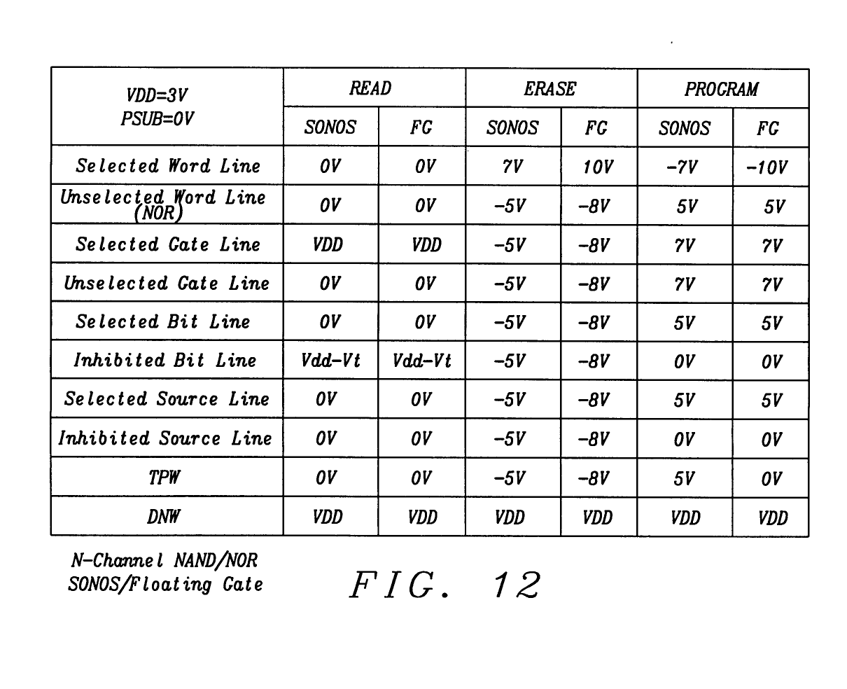

FIG. 11 is a graph of threshold voltage levels for various embodiments of an N-channel transistor floating gate and SONOS charge trapping NOR flash memory cells. In this case the threshold voltages for the erased state and the programmed state are reversed from the example of FIG. 7. The programmed state for the N-channel charge retaining transistors M0 has a threshold voltage level distribution that has an upper limit Vt0H of approximately −2V. The erased state for the N-channel charge retaining transistors M0 has a threshold voltage level distribution that has a lower limit Vt1L of 1.5V. During a read operation, the read reference voltage level V_{R} for the charge retaining transistors M0 is approximately 0V. The threshold voltage of the select transistor MS has a nominal voltage level of approximately 0.7V with a lower limit VtL of approximately 0.6V and a upper limit VtH of approximately 0.8V

FIG. 12 is a table illustrating the voltage conditions for operating an array of an array of N-channel floating gate and SONOS charge trapping transistor NOR flash memory cells for reading, erasing, and programming, selected of N-channel floating gate and SONOS charge trapping transistors. For erasing selected N-channel floating gate transistors of NOR flash memory cells, a positive erase voltage level of approximately 10V+/−2V applied to the control gate and a negative erase voltage level of approximately −8V+/−2V is applied to the triple P-well and coupled to the drains and sources for the N-channel charge retaining transistors M0. The voltage level of the power supply voltage source is applied to the deep N-well. For the selected N-channel SONOS charge trapping transistors of NOR memory cells, the positive erase voltage level of approximately 7V+/−1V is applied to the control gate and a negative erase voltage level of approximately −5V+/−1V is applied to the triple P-well and coupled to the drains and sources for the N-channel charge retaining transistors M0. The voltage level of the power supply voltage source is applied to the deep N-well. The voltage levels of the positive and negative erase voltage level are split such that the voltage field between the charge retaining (floating gate, SONOS charge trapping) layer and the triple P-well is sufficiently large to trigger the Fowler-Nordheim tunneling. The voltage levels of the positive and negative erase voltage level have magnitudes that are equal to or less than the drain to source breakdown voltage BV_{DS} of the peripheral circuitry generating and distributing the positive and negative erase biasing voltages.

For programming selected N-channel floating gate transistors of NOR flash memory cells, a negative program voltage level of approximately −10V+/−2V applied to the control gate and a positive program voltage level of approximately 5V+/−2V is applied to the bit lines LBL and the source lines LSL and thus to the drains and sources of the selected N-channel floating gate transistors M0 of the NOR flash memory cells. The ground reference voltage level (0V) is applied to the triple P-well and the voltage level of the power supply voltage source (VDD) is applied to the deep N-well.

For programming selected N-channel SONOS charge trapping transistors of the NOR flash memory cells, a negative program voltage level of approximately −7V+/−1V applied to the control gate and a positive program voltage level of approximately 5V+/−1V is applied to the bit lines LBL and the source lines LSL and thus to the drains and sources of the selected N-channel floating gate transistors M0 of the NOR flash memory cells. The ground reference voltage level (0V) is applied to the triple P-well and the voltage level of the power supply voltage source (VDD) is applied to the deep N-well. The voltage levels of the positive and negative program voltage level are split such that the voltage field between the charge retaining (floating gate, SONOS charge trapping) layer and the triple P-well is sufficiently large to trigger the Fowler-Nordheim tunneling. The voltage levels of the positive and negative program voltage level have magnitudes that are equal to or less than the drain to source breakdown voltage BV_{DS} of the peripheral circuitry generating and distributing the positive and negative program biasing voltages.

The positive program voltage level is applied equally to the bit lines LBL and the source lines LSL and thus to the drains and sources of the selected N-channel floating gate transistors M0 of the NOR flash memory cells to insure that the voltage difference between the drains and sources is less than the drain-to-source breakdown voltage BV_{DS}. Insuring that the voltage difference between the drains and sources is less than the drain-to-source breakdown voltage BV_{DS} allows the gate length of the N-channel charge retaining transistors M0 to be limited only by the minimum feature size (λ) of the technology being employed to implement the N-channel SONOS charge trapping transistors of the NOR flash memory cells.

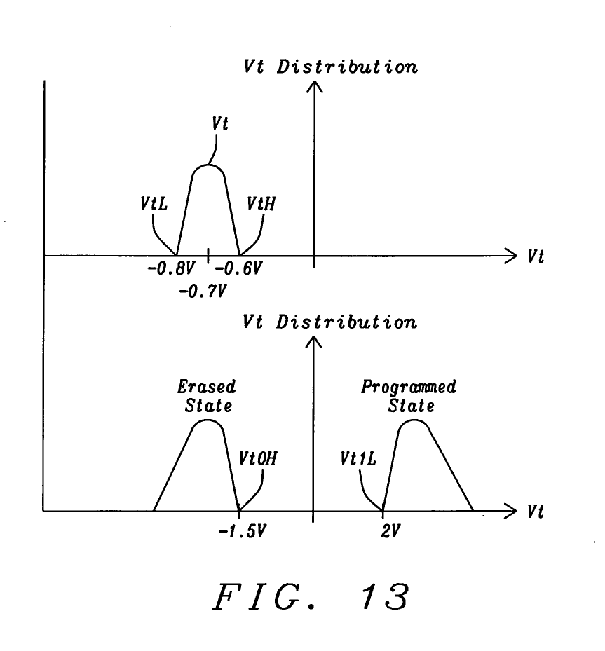

FIG. 13 is a graph of threshold voltage levels for various embodiments of a P-channel transistor floating gate and SONOS charge trapping NOR flash memory cells. In this case the threshold voltages for the erased state and the programmed state are reversed from the example of FIG. 9. The erased state for the P-channel charge retaining transistors M0 of the NOR flash memory cells has a threshold voltage level distribution that has an upper limit Vt0H of approximately −1.5V. The programmed state for the P-channel charge retaining transistors M0 of the NOR flash memory cells has a threshold voltage level distribution that has a lower limit Vt1L of 2V. During a read operation, the read reference voltage level V_{R} for the P-channel charge retaining transistors M0 of the NOR flash memory cells is approximately 0V. The threshold voltage of the select transistor MS has a nominal voltage level of approximately −0.7V with an upper limit Vt1H of approximately −0.6V and a lower limit Vt1L of approximately −0.8V

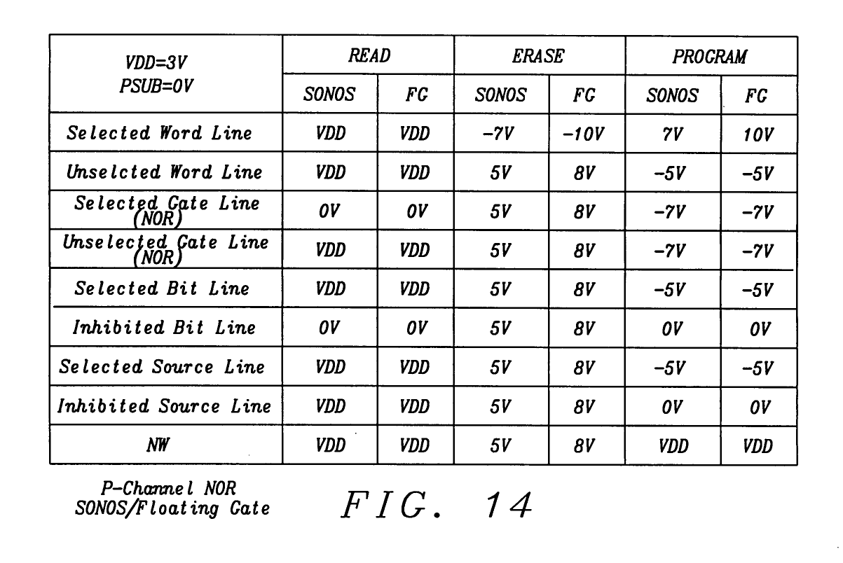

FIG. 14 is a table illustrating the voltage conditions for operating an array of an array of P-channel floating gate and SONOS charge trapping transistor NOR flash memory cells for reading, erasing, and programming, selected of P-channel floating gate and SONOS charge trapping transistors. For erasing selected P-channel floating gate charge retaining transistors M0 of the NOR flash memory cells, a negative erase voltage level of approximately −10V+/−2V applied to the control gate and a positive erase voltage level of approximately 8V+/−2V is applied to the N-type diffusion well N-well and coupled to the drains and sources for the P-channel floating gate charge retaining transistors M0 of the NOR flash memory cells. For erasing the selected P-channel SONOS charge retaining transistors M0 of the NOR flash memory cells, a negative erase voltage level of approximately −7V+/−1V is applied to the control gate and a positive erase voltage level of approximately 5V+/−1V is applied to the N-well and coupled to the drains and sources for the P-channel SONOS charge retaining transistors M0 of the NOR flash memory cells. The voltage levels of the positive and negative erase voltage level are split such that the voltage field between the charge retaining (floating gate, SONOS charge trapping) layer and the N-type diffusion well N-WELL is sufficiently large to trigger the Fowler-Nordheim tunneling. The voltage levels of the positive and negative erase voltage level have magnitudes that are equal to or less than the drain to source breakdown voltage BV_{DS} of the peripheral circuitry generating and distributing the positive and negative erase biasing voltages.

For programming selected P-channel floating gate transistors of NOR flash memory cells, a positive program voltage level of approximately 10V+/−2V applied to the control gate and a negative program voltage level of approximately—−5V+/−1V is applied to the bit lines LBL and the source lines LSL and thus to the drains and sources of the selected P-channel floating gate transistors M0 of the NOR flash memory cells. The voltage level of power supply voltage source (VDD) is applied to the N-type diffusion well N-WELL.

For programming selected P-channel SONOS charge trapping transistors of the NOR flash memory cells, a positive program voltage level of approximately 7V+/−2V applied to the control gate and a negative program voltage level of approximately −5V+/−1V is applied to the bit lines LBL and the source lines LSL and thus to the drains and sources of the selected P-channel floating gate transistors M0 of the NOR flash memory cells. The voltage level of power supply voltage source (VDD) is applied to the N-type diffusion well N-WELL. The voltage levels of the positive and negative program voltage level are split such that the voltage field between the charge retaining (floating gate, SONOS charge trapping) layer and the N-well is sufficiently large to trigger the Fowler-Nordheim tunneling. The voltage levels of the positive and negative program voltage level have magnitudes that are equal to or less than the drain to source breakdown voltage BV_{DS} of the peripheral circuitry generating and distributing the positive and negative program biasing voltages.

The negative program voltage level is applied equally to the bit lines LBL and the source lines LSL and thus to the drains and sources of the selected P-channel floating gate transistors M0 of the NOR flash memory cells to insure that the voltage difference between the drains and sources is less than the drain-to-source breakdown voltage BV_{DS}. Insuring that the voltage difference between the drains and sources is less than the drain-to-source breakdown voltage BV_{DS} allows the gate length of the charge retaining transistors M0 to be limited only by the minimum feature size (λ) of the technology being employed to implement the P-channel SONOS charge trapping transistors of the NOR flash memory cells.

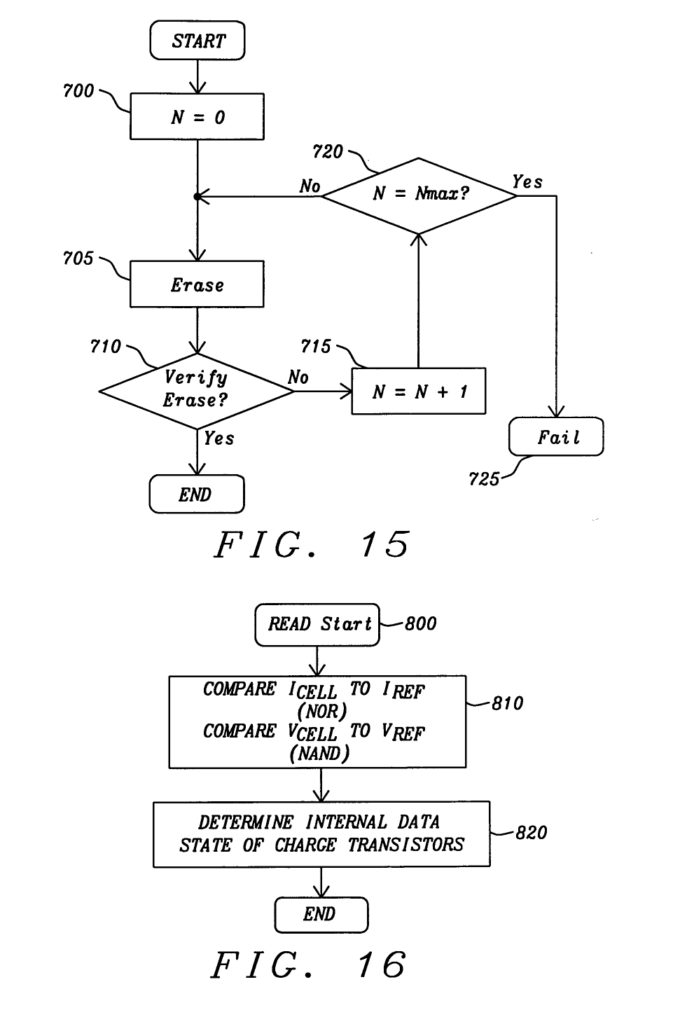

FIG. 15 is a flow chart of an erase operation for an array 405 of the charge retaining transistor NAND flash memory cells 300 and 315 of FIGS. 4a and 4b or a selected page of charge retaining transistor NOR flash memory cells 330 and 345 of FIGS. 4c and 4d. For a discussion of the erase operation of selected charge retaining transistor NAND flash memory cells 300 and 315 of FIGS. 4a and 4b or a selected page of charge retaining transistor NOR flash memory cells 330 and 345 of FIGS. 4c and 4d, refer now to FIGS. 4a-4d, 5, 6 and 15. For this discussion, the entire array 405 of the charge retaining transistor NAND flash memory cells 300 and 315 of FIGS. 4a and 4b are erased or the selected page of charge retaining transistor NOR flash memory cells 330 and 345 of FIGS. 4c and 4d that are connected to the word line WL0 are erased. The unselected pages of charge retaining transistor NOR flash memory cells 330 and 345 of FIGS. 4c and 4d are connected to the word lines WL1, WL2, WL3, . . . , WLm−1, and WLm. In FIG. 15 an input command is decoded to determine if it is an erase operation. If the command is for an erase operation the procedure begins by initializing an erase counter (Box 700). The entire array 405 of the charge retaining transistor NAND flash memory cells 300 and 315 of FIGS. 4a and 4b or the selected page of charge retaining transistor NOR flash memory cells 330 and 345 of FIGS. 4c and 4d that are connected to the word line WL0 are erased (Box 705). Refer now to FIGS. 8, 10, 12, and 14 for voltage levels applied to the array 405 of the charge retaining transistor NAND flash memory cells 300 and 315 of FIGS. 4a and 4b or the selected page of charge retaining transistor NOR flash memory cells 330 and 345 of FIGS. 4c and 4d to erase the entire array 405 of the charge retaining transistor NAND flash memory cells 300 and 315 of FIGS. 4a and 4b or the selected page of charge retaining transistor NOR flash memory cells 330 and 345 of FIGS. 4c and 4d. The voltage levels are determined according whether the charge retaining transistor NAND or NOR flash memory cells 300, 315, 330, and 345 are floating gate or SONOS charge trapping flash nonvolatile transistors and are N-channel or P-channel flash nonvolatile transistors. Further, the erase threshold voltage level to which the charge retaining transistor NAND or NOR flash memory cells 300, 315, 330, and 345 are to be erased as shown in FIGS. 7, 9, 11, and 13 determine the erase biasing voltage levels. The unselected charge retaining transistor NAND or NOR flash memory cells 300, 315, 330, and 345 are similarly biased according the voltage levels of FIGS. 8, 10, 12, and 14 to inhibit any disturbances during the erasing operation.

The array 405 of the charge retaining transistor NAND flash memory cells 300 and 315 of FIGS. 4a and 4b or the selected page of charge retaining transistor NOR flash memory cells 330 and 345 of FIGS. 4c and 4d are then verified (Box 710). Refer back to FIGS. 8, 10, 12, and 14 for the biasing voltage levels of the charge retaining transistor NAND or NOR flash memory cells 300, 315, 330, and 345 to be verified. The read bias voltage level V_{RDB} is applied as the power supply voltage source VDD to the selected global source lines GSL0, . . . , GSLn and the ground reference voltage level is applied to the global bit lines GBL0, . . . , GBLn. The sense amplifier detects the voltage level of the global bit lines GBL0, . . . , GBLn and thus the selected local bit lines. Dependent upon the erased threshold voltage level and the structure of the charge retaining transistors M0, M1, . . . , Mn, the charge retaining transistors M0, M1, . . . , Mn are considered to have passed if the detected voltage is either the voltage level of the power supply voltage source VDD or the ground reference voltage level.

If any of the selected charge retaining transistor NAND or NOR flash memory cells 300, 315, 330, and 345 have not been sufficiently erased such that their threshold voltage level has achieved the appropriate limit of the erased threshold voltage level, they have failed the verification (Box 710) of the array 405 of the charge retaining transistor NAND flash memory cells 300 and 315 of FIGS. 4a and 4b are erased and the selected page of charge retaining transistor NOR flash memory cells 330 and 345 of FIGS. 4c and 4d, the erase counter is incremented (Box 715) and the erase counter is compared (Box 720) to the maximum erase count Nmax. If the erase counter exceeds the maximum erase count Nmax, the nonvolatile memory device 400 has failed (Box 725). If the erase counter does not exceed the maximum erase count Nmax, the array 405 of the charge retaining array 405 of the charge retaining transistor NAND flash memory cells 300 and 315 of FIGS. 4a and 4b are erased and the selected page of charge retaining transistor NOR flash memory cells 330 and 345 of FIGS. 4c and 4d are erased or the selected page of charge retaining transistor NOR flash memory cells 330 and 345 of FIGS. 4c and 4d is erased (Box 705) and erase verified (Box 710) until all of the charge retaining transistors M0, M1, . . . , Mn pass. If the charge retaining transistors M0 are successfully erased, the page erase operation is ended. The voltage levels of the positive and negative program voltage levels as applied to the control gates and the triple well T-WELL or single diffusion well S-WELL are split such that the voltage field between the charge retaining (floating gate, SONOS charge trapping) layer and the triple well T-WELL or single diffusion well S-WELL is sufficiently large to trigger the Fowler-Nordheim tunneling. The voltage levels of the positive and negative program voltage levels have magnitudes that are equal to or less than the drain to source breakdown voltage BV_{DS} of the peripheral circuitry generating and distributing the positive and negative program biasing voltages.

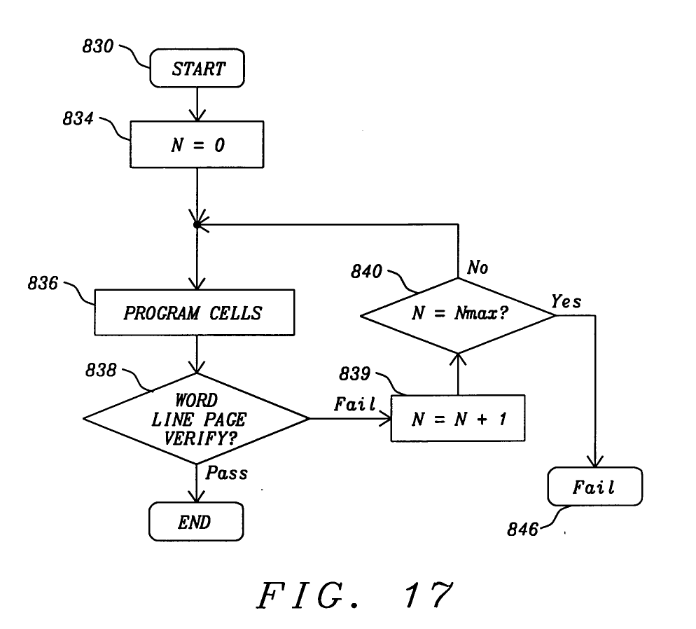

FIG. 16 is a flow chart of a read operation for selected charge retaining transistors M0, M1, . . . , Mn of an array 405 of the charge retaining transistor NAND flash memory cells 300 and 315 of FIGS. 4a and 4b or a selected page of charge retaining transistor NOR flash memory cells 330 and 345 of FIGS. 4c and 4d. FIGS. 8, 10, 12, and 14 are tables illustrating the voltage levels applied to the terminals for various embodiments of an array of dual charge retaining transistor NOR flash memory cells for a read operation. For this discussion, the selected charge retaining transistors M0 to be read are connected to the word line WL0 and the unselected charge retaining transistors M1, . . . , Mn are connected to the word lines WL1, WL2, WL3, . . . , WLm−1, and WLm. Referring to FIGS. 4a-4d and 16, the read operation is started (Box 800) by the word line voltage control circuit 415 applying a pass voltage level Vpass selected word lines WL1, WL2, WL3, . . . , WLm−1, and WLm. The read reference voltage level V_{R} is applied to the selected word line WL0. The read reference voltage level VR is the ground reference voltage level (0V) for the N-channel charge retaining transistors M0, M1, . . . , Mn of FIGS. 8, 12, and 13 and the power supply voltage source (VDD) for the P-channel charge retaining transistors M0, M1, . . . , Mn of FIGS. 10 and 14. The pass voltage level Vpass is approximately 4.5V for the N-channel charge retaining transistors M0, M1, . . . , Mn of FIGS. 8, 12, and 13 and approximately the power supply voltage level less 4.5 V for the P-channel charge retaining transistors M0, M1, . . . , Mn of FIGS. 10 and 14.

The sense amplifier 430 is activated to be connected to the global source lines GSL0, . . . , GSLn. The selected bit line select signals BLG0 and BLG1 are set to the gate select voltage level V_{RGS} of the power supply voltage source (VDD) for the N-channel charge retaining transistors M0, M1, . . . , Mn of the N-channel charge retaining transistors M0, M1, . . . , Mn of FIGS. 8, 12, and 13 and of the ground reference voltage level of the P-channel charge retaining transistors M0, M1, . . . , Mn of FIGS. 10 and 14 to turn on the bit line select transistors 435a, . . . , 435n to pre-charge the local bit lines LBL0, LBL1, . . . , LBLn−1, and LBLn to a read bias voltage level V_{RDB}. The selected source line select signals SLG0 and SLG1 set to the gate select voltage level V_{RGS} to the source line select transistors 440a, . . . , 440n to apply the power supply voltage level VDD for the N-channel charge retaining transistors M0, M1, . . . , Mn of FIGS. 8, 12, and 13 or the ground reference voltage level for the P-channel charge retaining transistors M0, M1, . . . , Mn of FIGS. 10 and 14 to the local source lines LSL0, LSL1, . . . , LSLn−1, and LSLn. A select gate signal SG is activated by the word line voltage control circuit 415 to the voltage level of power supply voltage source (VDD) for the N-channel charge retaining transistors M0, M1, . . . , Mn of FIGS. 8, 12, and 13 or to the ground reference voltage level (0V) for the P-channel charge retaining transistors M0, M1, . . . , Mn of FIGS. 10 and 14. A cell current Icell passes through the charge retaining transistors M0, M1, . . . , Mn of the selected dual charge retaining transistor NOR flash memory cells 310 to the sense amplifier 655. The unselected bit line select signals BLG0 and BLG1 and the unselected source line select signals SLG0 and SLG1 are set to the read unselect voltage level V_{RUS} to deactivate the unselected local bit lines LBL0, LBL1, . . . , LBLn−1, and LBLn and the unselected local source lines LSL0, LSL1, . . . , LSLn−1, and LSLn.

The sense amplifier 655 employs the reference current Iref to determine the internal data state of the charge retaining transistors M0 connected to the selected word line WL0 or WL1. For the charge retaining transistor NOR flash memory cells 330 and 345 of FIGS. 4c and 4d, the cell current Icell is compared (Box 810) to the reference current Iref. The cell current Icell indirectly reflects the comparison of cell voltage Vcell to a reference voltage Vref through a load resistance integrated with the sense amplifier 655. The cell current Icell is greater than 10 μa and therefore has sufficient speed for sensing using the current comparison. Alternately, for the charge retaining transistor NAND flash memory cells 300 and 315 of FIGS. 4a and 4b, it is difficult to use current comparison approach because the current is very low. Therefore, in the charge retaining transistor NAND flash memory cells 300 and 315 of FIGS. 4a and 4b, the sense amplifier 655 compares the cell voltage Vcell present at the bit line BL is compared (Box 810) to the reference voltage Vref. The data state of the charge retaining transistors M0 or M1 connected to the selected word line WL0 or WL1 are then determined (Box 820). Upon the determination (Box 820) of the data state for the selected page of the array 405 of the charge retaining transistor NAND flash memory cells 300 and 315 of FIGS. 4a and 4b or the selected page of charge retaining transistor NOR flash memory cells 330 and 345 of FIGS. 4c and 4d, the read operation for the selected page of the array 405 of the charge retaining transistor NAND flash memory cells 300 and 315 of FIGS. 4a and 4b or the selected page of charge retaining transistor NOR flash memory cells 330 and 345 of FIGS. 4c and 4d is ended.

FIG. 17 is a flow chart of a program operation for a word line page of array 405 of the charge retaining transistor NAND flash memory cells 300 and 315 of FIGS. 4a and 4b or the selected page of charge retaining transistor NOR flash memory cells 330 and 345 of FIGS. 4c and 4d. FIGS. 8, 10, 12, and 14 are tables of the voltage levels applied to the terminals of various embodiments an array 405 of the charge retaining transistor NAND flash memory cells 300 and 315 of FIGS. 4a and 4b or the selected page of charge retaining transistor NOR flash memory cells 330 and 345 of FIGS. 4c and 4d for a program operation. For a discussion of the program operation of selected charge retaining transistors M0, M1, . . . , Mn, refer now to FIGS. 8, 10, 12, 14 and 17. For this discussion, the selected charge retaining transistors M0 are connected to the word line WL0 and the unselected charge retaining transistors M1, . . . , Mn are connected to the word lines WL1, WL2, WL3, . . . , WLm−1, and WLm. In FIG. 17 an input command is decoded to determine if it is a program operation. If the command is for a programming operation the operation is started (Box 830) with initializing (Box 834) counter N is to a program count. The selected charge retaining transistors M0 connected to the selected word line WL0 are programmed (Box 836). The program inhibit voltage level (V_{PGMI}) is applied to the unselected word lines WL1, WL2, WL3, . . . , WLm−1, and WLm. A program voltage V_{PGM} is applied to the word line WL0 to set the threshold voltage level of the selected charge retaining transistors M0 to the program threshold voltage level. The program threshold voltage level being as shown in FIGS. 8, 10, 12, and 14 for each of the embodiments of the charge retaining transistors M0, M1, . . . , Mn. The bit line select signals BLG0 and BLG1 are set to the voltage level of a bit line select voltage level V_{BLS} to turn on the bit line select transistors 435a, . . . , 435n to connect the global bit lines GBL0, . . . , GBLn to set the local bit lines LBL0, LBL1, . . . , LBLn−1, and LBLn to the drain/source program voltage level as shown in FIGS. 8, 10, 12, and 14. The selected source line select signals SLG0 and SLG1 are set to the voltage level of a source line select voltage level V_{BLS} to turn on the source line select transistors 435a, . . . , 435n to connect the global source lines GSL0, . . . , GSLn to set the local source lines LSL0, LSL1, . . . , LSLn−1, and LSLn to the to apply drain/source program voltage level as shown in FIGS. 8, 10, 12, and 14 to the selected charge retaining transistors M0. The drain/source program voltage is applied equally to the local bit lines LBL0, LBL1, . . . , LBLn−1, and LBLn and the local source lines LSL0, LSL1, . . . , LSLn−1, and LSLn to insure that the voltage difference between the drains and sources is less than the drain-to-source breakdown voltage BV_{DS}. Insuring that the voltage difference between the drains and sources is less than the drain-to-source breakdown voltage BV_{DS} allows the gate length of the charge retaining transistors M0, M1, . . . , Mn to be limited only by the minimum feature size (λ) of the technology being employed to implement the P-channel SONOS charge trapping transistors of the NOR flash memory cells.

Upon completion of the programming of the selected page of the charge retaining transistors M0, the selected page is then program verified (Box 838). The unselected word lines WL1, WL2, WL3, . . . , WLm−1, and WLm are connected to receive the read pass voltage level V_{PASS} and the unselected upper word line WL0 of the selected word line page of charge retaining transistors M0 is connected to receive the read voltage V_{R}.

The sense amplifier 655 is activated to be connected to the global bit lines GBL0, . . . , GBLn. The selected bit line select signals BLG0 and BLG1 are set to the voltage level of a read select voltage level V_{RGS} to turn on the bit line select transistors 435a, . . . , 435n to connect the global bit lines GBL0, . . . , GBLn to set the local bit lines LBL0, LBL1, . . . , LBLn−1, and LBLn to the read bias voltage level as shown in FIGS. 8, 10, 12, and 14. The selected source line select signals SLG0 and SLG1 are set to the voltage level of a read select voltage level V_{RGS} to turn on the source line select transistors 435a, . . . , 435n to connect the global source lines GSL0, . . . , GSLn to set the local source lines LSL0, LSL1, . . . , LSLn−1, and LSLn to the to apply either the power supply voltage level VDD or the ground reference voltage level dependent upon the structure of the charge retaining transistors M0, M1, . . . , Mn as shown in FIGS. 8, 10, 12, and 14. The sense amplifier 655 determines if the selected charge retaining transistors M1 are programmed according to the criteria detailed in FIGS. 7, 9, 11, and 13. If the selected charge retaining transistors M1 are not programmed according to the criteria of FIGS. 7, 9, 11, and 13, the program counter (N) is incremented (Box 839) and the program count is examined (Box 840) to determine if it equal to the maximum program count Nmax. If the program count exceeds the maximum program count Nmax, the nonvolatile memory device 400 has failed (Box 846). If the program count does not exceed the maximum program count Nmax, the selected page of the charge retaining transistors M0, M1, . . . , Mn is programmed (Box 836) again and then program verified (Box 838) again. The programming (Box 836) and program verifying (Box 838) continues iteratively, until the selected page of the charge retaining transistors M0 of the array 405 of the charge retaining transistor NAND flash memory cells 300 and 315 of FIGS. 4a and 4b or the selected page of charge retaining transistor NOR flash memory cells 330 and 345 of FIGS. 4c and 4d are programmed. Upon completion of the programming (Box 836) and verification (Box 838) of the charge retaining transistors M0 of the upper word line WL0, the programming process ends.

The embodiments of the array 405 of the charge retaining transistor NAND flash memory cells 300 and 315 of FIGS. 4a and 4b or the selected page of charge retaining transistor NOR flash memory cells 330 and 345 of FIGS. 4c and 4d are shown to be implementable in various devices structures employing either a floating gate or SONOS (or MONOS) charge trapping layer that is formed in a triple well or single well configuration. Further, the array 405 of the charge retaining transistor NAND flash memory cells 300 and 315 of FIGS. 4a and 4b or the selected page of charge retaining transistor NOR flash memory cells 330 and 345 of FIGS. 4c and 4d may be implemented as either N-channel or P-channel transistors. The voltage level employed for the programming the charge retaining transistors M0, M1, . . . , Mn provide equal program voltage levels applied to the drains and sources of the charge retaining transistors M0, M1, . . . , Mn to avoid punch-through. The voltage and current operating levels are such that the device size is minimized to permit a high degree of cell scalability. The select transistor MS of each charge retaining transistor NAND flash memory cells 300 and 315 of FIGS. 4a and 4b or each of charge retaining transistor NOR flash memory cells 330 and 345 of FIGS. 4c and 4d makes the charge retaining transistor NAND flash memory cells 300 and 315 of FIGS. 4a and 4b or each of charge retaining transistor NOR flash memory cells 330 and 345 of FIGS. 4c and 4d essentially over-erase free. The positive and negative program and erase voltage levels applied to the control gates and the triple well T-WELL or diffusion well S-WELL of the charge retaining transistors M0, M1, . . . , Mn are split such that the voltage field between the charge retaining (floating gate, SONOS charge trapping) layer and the triple well T-WELL is sufficiently large to trigger the Fowler-Nordheim tunneling. The voltage levels of the positive and negative program and erase voltage level have magnitudes that are equal to or less than the drain to source breakdown voltage BV_{DS} of the peripheral circuitry generating and distributing the positive and negative program biasing voltages.

The fabrication of the array 405 of the charge retaining transistor NAND flash memory cells 300 and 315 of FIGS. 4a and 4b or the charge retaining transistor NOR flash memory cells 330 and 345 of FIGS. 4c and 4d is based on—current standard flash nonvolatile memory technology. Dependent upon the device structures for the charge retaining transistors M0, M1, . . . , Mn, the programming and erasing process is selected to be Fowler-Nordheim Channel Tunneling or Fowler-Nordheim Edge Tunneling.

While this invention has been particularly shown and described with reference to the preferred embodiments thereof, it will be understood by those skilled in the art that various changes in form and details may be made without departing from the spirit and scope of the invention.

The invention claimed is:

1. An array of flash nonvolatile memory cells comprising:
an array of nonvolatile memory cells arranged in rows and columns;
a plurality bit lines, wherein each bit line is associated with and in parallel with one column of the nonvolatile memory cells; and
a plurality of source lines, wherein each source is associated with and in parallel with one column of the nonvolatile memory cells and in parallel with the one bit line associated with the associated column of nonvolatile memory cells.

2. The array flash nonvolatile memory cells of claim 1 wherein the nonvolatile memory cells comprise at least one charge retaining transistor.

3. The array flash nonvolatile memory cells of claim 2 wherein the at least one charge retaining transistor is a floating gate or SONOS charge trapping transistor.

4. The array flash nonvolatile memory cells of claim 1 wherein the nonvolatile memory cells are flash NAND or NOR nonvolatile memory cells.

5. The array flash nonvolatile memory cells of claim 3 wherein the charge retaining transistors are N-channel and a P-channel charge retaining transistors

6. The array flash nonvolatile memory cells of claim 2 wherein the nonvolatile memory cells further comprise a select transistor is series with the at least one charge retaining transistor.

7. A method for operating a charge retaining transistor nonvolatile memory cell comprising:
applying approximately equal program voltage levels to a drain and a source of a selected charge retaining transistor such that the difference in the voltage between the drain and the source of the selected charge retaining transistor is less than a drain to source breakdown voltage of the selected charge retaining transistor to prevent drain-to-source punch through.

8. A method for operating a charge retaining transistor nonvolatile memory cell comprising:
applying a control gate program voltage level to a control gate of a selected charge retaining transistor such that the magnitude of the control gate program voltage level is less than a breakdown voltage level of peripheral circuitry generating and distributing the control gate program voltage level; and
applying a bulk region program voltage level to a bulk region of the selected charge retaining transistor such that the magnitude of the bulk region program voltage level is less than a breakdown voltage level of peripheral circuitry generating and distributing the control gate program voltage level;
wherein a voltage difference between the control gate program voltage and the bulk region program voltage is sufficiently large to trigger Fowler-Nordheim tunneling.
